(19) United States
(12) Patent Application Publication
(10) Pub. No.: US 2024/0072443 A1
(43) Pub. Date: Feb. 29, 2024

(54) DUAL BAND FAN OUT DEVICE AND METHOD

(71) Applicant: Taiwan Semiconductor Manufacturing Co., Ltd., Hsinchu (TW)

(72) Inventor: Wen-Shiang Liao, Toufen Township (TW)

(21) Appl. No.: 18/151,843

(22) Filed: Jan. 9, 2023

Related U.S. Application Data
(63) Continuation-in-part of application No. 17/895,502, filed on Aug. 25, 2022.

(51) Int. Cl. H01Q 9/04; H01Q 1/38; H01Q 1/50

(52) U.S. Cl. CPC H01Q 9/0407; H01Q 1/38; H01Q 1/50

(57) ABSTRACT

Embodiments provide an integrated package device and method of forming the same, the device having dual band functionality by way of a first antenna and a second antenna. The first antenna can transmit/receive high frequency radio frequency (RF) signals and the second antenna can transmit/receive lower frequency RF signals. A high-k dielectric zone is provided aligned to the first antenna. An oscillation region may be aligned to the embedded antenna(s).

### PRIORITY CLAIM AND CROSS-REFERENCE

This patent is a continuation-in-part of U.S. application Ser. No. 17/895,502, filed on Aug. 25, 2022, which application is hereby incorporated by reference herein as if reproduced in its entirety.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 10A, 10B, and 11 through 15 illustrate various views of intermediate steps during a process for forming a package component in accordance with some embodiments.

FIG. 16 illustrates a cross-sectional view of an integrated circuit die in accordance with some embodiments.

FIGS. 17 through 23A, 23B, and 24 through 25 illustrate various views of intermediate steps during a process for forming a package component in accordance with some embodiments.

FIG. 26 illustrates flow diagrams for a process of transmitting and receiving a transmission signal, in accordance with some embodiments.

FIGS. 27 through 36A, 36B, 37 through 40, 41A, 41B, and 42 through 44 illustrate various views of intermediate steps during a process for forming a dual band package component in accordance with some embodiments.

FIG. 45 illustrates a dual band package component in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Devices with embedded antennas face unique challenges. Using printed circuit boards and/or complementary metal oxide semiconductors and associated metal layers may be used to form antennas, however, performance of such antennas is dominated by the large capacitance between metal layers. Further, layout is difficult to accommodate antennas to avoid interference from other metal structures in the devices. Also, space is limited and antennas may be weak or contain a lot of noise in transmission and/or reception. Integrated antennas typically suffer from process integration challenges, need large chip areas, and have high relative cost.

Embodiments provide a structure and device having an integrated antenna which is suitable for transmitting and receiving in 5G/6G radio frequency ranges, such as at around the nominal 12.4 GHz range for 5G/6G, and in the upcoming 5th generation around the nominal 5.8 GHz range and 5th generation high frequency ranges (29 GHz to 38 GHz and 77 GHz to 120 GHz.) Other frequencies are possible and contemplated. Other embodiments provide a dual band package for sending/receiving dual signals at different frequencies. A high-k zone or high-k region is used for the high frequency antenna. The dual band package utilizes an integrated fan out (InFO) design and formation process to build utilizing cost-effective techniques.

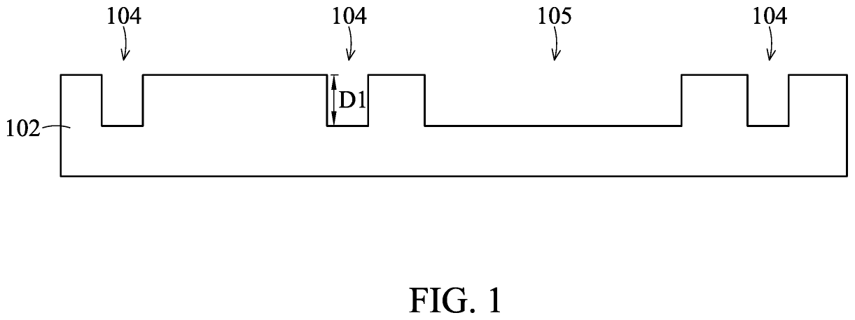

FIGS. 1 through 20 illustrate cross-sectional views and top down views of intermediate steps during a process for forming a first package component 100, in accordance with some embodiments. A first package region is illustrated. Additional package region may be formed at the same time as the first package region and may be understood as being like unto the first package region. The package regions are formed using the same base wafer substrate and later singulated and attached to a substrate, which is described following the formation of the first package component 100.

In FIG. 1, a substrate 102 is provided. The substrate 102 may be a semiconductor substrate, such as a bulk semiconductor, a semiconductor-on-insulator (SOI) substrate, or the like, which may be doped (e.g., with a p-type or an n-type dopant) or undoped. The substrate 102 may be a wafer, such as a silicon wafer having a thickness between about 500 and 2000 μm. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 102 is patterned to form recesses or trenches therein. The recesses 104 are formed for conductive vias which are subsequently used to route signals to subsequently provided integrated circuit dies. The recesses 105 are formed which align to a subsequently formed oscillation cavity for an integrated antenna an oscillation region. The recesses may have a depth D1 between about 50 μm and 200 μm, though other depths may be used. The recesses 104/105 may be formed using any suitable process, such as by an acceptable photoetching technique. For example, in one embodiment, a photoresist is formed over the substrate 102 and patterned into a photomask using a photolithography process. The photomask is then used to protect areas of the substrate 102 which are not to be etched. Then an etching technique, such as a reactive ion etch or wet etch may be used to etch the substrate 102 to a desired depth. For example, a timed etch may be used. While each of the recesses 104/105 is shown as having the same depth, in some embodiments, the recesses 104 may be deeper or shallower than the recesses 105. The recesses 104 may be any desired width, such as about 2 μm to about 50 μm and the recesses 105 may have a width and length (the length being in a perpendicular horizontal direction to the width) that corresponds to a subsequently formed antenna. In some embodiments, for example, the width and length of the recesses 105 may each be between about 3 mm and 80 mm.

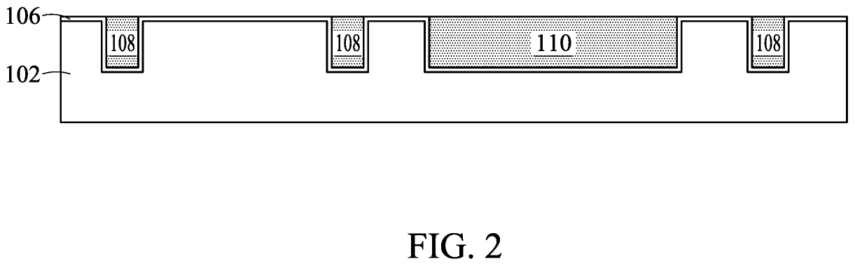

In FIG. 2, a liner layer 106 may be formed in each of the recesses 104/105. The liner layer 106 may be formed by a thermal oxidation process which uses steam or ambient oxygen to oxidize exposed portions of the substrate 102. When the substrate 102 is silicon, for example, the liner layer 106 may be silicon oxide. In other embodiments, the liner layer 106 may include a conformally deposited insulating material, such as silicon oxide, silicon nitride, silicon oxynitride, the like, or combination thereof, deposited by chemical vapor deposition (CVD), physical vapor deposition (PVD), atomic layer deposition (ALD), or the like.

After forming the liner layer 106, a metal fill 108 is deposited in the remaining portion of the recesses 104 and a metal fill 110 is deposited in the remaining portion of the recesses 105. The metal fill 108 and 110 may include any suitable material, such as copper, titanium, aluminum, silver, tungsten, cobalt, the like, or combinations (or alloys) thereof. The metal fill 108 and metal fill 110 may be deposited using any suitable process, such as by CVD, PVD, ALD, electroplating, electrochemical plating, and the like. In some embodiments, a seed layer is formed over the dielectric layer liner layer 106 in the recesses 104 and 105. The seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist (not shown) is then formed and patterned on the seed layer. The photoresist may be formed by spin coating or the like and may be exposed to light for patterning. The pattern of the photoresist corresponds to the recesses 104 and 105. The patterning forms openings through the photoresist to expose the seed layer in the recesses 104 and 105. A conductive material is formed in the openings of the photoresist and on the exposed portions of the seed layer. The conductive material may be formed by plating, such as electroplating or electroless plating, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metal fill 108 and metal fill 110. Portions of the metal fill 108 and 110 which may extend above the substrate 102 may be removed and leveled to the surface of the substrate 102 using a planarization process, such as a chemical mechanical polishing (CMP) process.

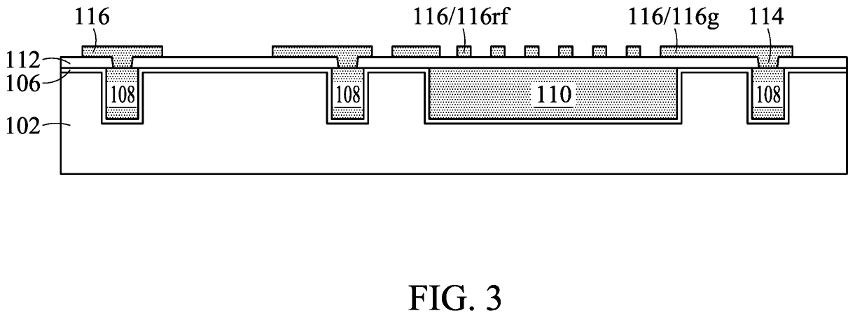

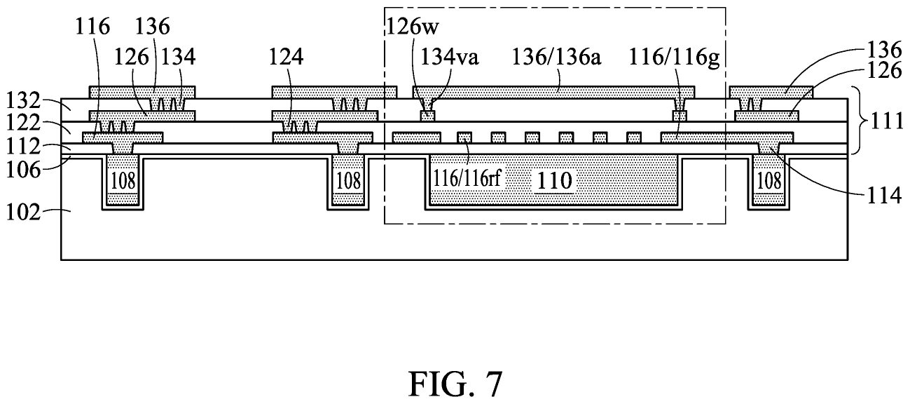

In FIG. 3, a first metallization pattern 116 for a redistribution structure 111 (see FIG. 7) may be formed over a dielectric layer 112 of the redistribution structure 111. The dielectric layer 112 may be formed on the liner layer 106 and over the metal fills 108 and 110. The first metallization pattern 116 may penetrate through the dielectric layer 112 using through vias 114 to contact and couple the metal fills 108 to the first metallization pattern 116. The bottom surface of the dielectric layer 112 may be in contact with the top surface of the liner layer 106. In some embodiments, the dielectric layer 112 is formed of a polymer, such as polybenzoxazole (PBO), polyimide (PI), benzocyclobutene (BCB), or the like. In other embodiments, the dielectric layer 112 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 112 may be formed by any acceptable deposition process, such as spin coating, CVD, plasma enhanced CVD (PECVD), laminating, the like, or a combination thereof. After depositing the dielectric layer 112, openings may be made through the dielectric layer 112 using an acceptable photoetching process, such as described above, the openings corresponding to the through vias 114.

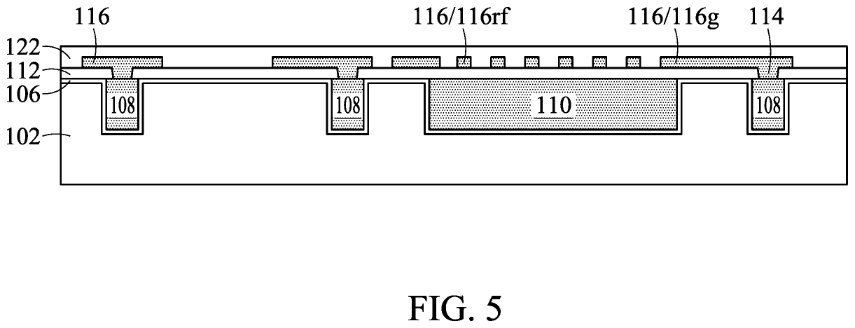

The first metallization pattern 116 may be formed on the dielectric layer 112 and the through vias 114 formed through the openings in the dielectric layer 112 in a the same process or in different processes. The first metallization pattern 116 and through vias 114 may be formed using processes and materials similar to those used to form the metal fills 108 and 110. For example, to form first metallization pattern 116 and through vias 114 at the same process, a seed layer may be formed over the dielectric layer 112 and in the openings through the dielectric layer 112 to contact exposed upper surfaces of the metal fills 108. The seed layer may be a single or composite metal layer. A photoresist may then be formed and patterned on the seed layer to form openings therein corresponding to the first metallization pattern 116, which includes the through vias 114. A conductive material is formed in the openings of the photoresist and on the exposed portions of the seed layer. Then, the photoresist and portions of the seed layer on which the conductive material is not formed are removed. The remaining portions of the seed layer and conductive material form the first metallization pattern 116 and through vias 114. Other processes may be used. For example, in some embodiments, the through vias 114 may be formed first, followed by the first metallization pattern 116. In other embodiments, the first metallization pattern 116 may be formed within the dielectric layer 112 such that the upper surface of the dielectric layer 112 (e.g., see dielectric layer 118 in FIG. 5) may be leveled with the upper surface of the first metallization pattern 116.

The first metallization pattern 116 may include a metal grate 116rf which defines an outer portion of an oscillation region. The first metallization pattern 116 may also include a ground metal 116g which couples to the metal grate 116rf.

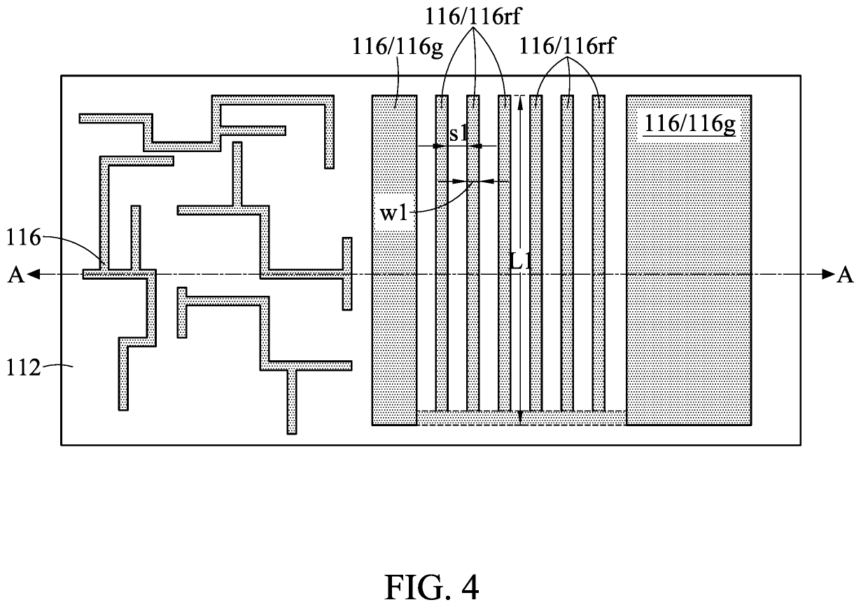

FIG. 4 illustrates a top down view of the structure of FIG. 3, in accordance with some embodiments. The reference line A-A corresponds to the cross-sectional view of FIG. 3. The dielectric layer 112 is shown as well as an example first metallization pattern 116. The metal grate 116rf is illustrated as having multiple parallel metal lines that are spaced apart from each other. These metal lines are used to amplify an antenna signal, which will be explained in greater detail below. The spacing s1 of the metal lines of the metal grate 116rf may be between about 0.1 μm and about 100 μm. The width wl of the metal lines of the metal grate 116rf may be between about 0.1 μm and about 100 μm. The length L1 of the metal lines of the metal grate 116rf may be between about 10 μm and about 10,000 μm. On one or both ends, as shown in dashed outline, the ends of the metal grate 116rf may all be coupled to each other and to the ground metal 116g.

In FIG. 5, the dielectric layer 122 may be formed on the first metallization pattern 116 and the dielectric layer 112. In some embodiments, the dielectric layer 122 is formed of a polymer, which may be a photo-sensitive material such as PBO, PI, BCB, or the like, that may be patterned using a lithography mask. In other embodiments, the dielectric layer 122 is formed of a nitride such as silicon nitride; an oxide such as silicon oxide, PSG, BSG, BPSG; or the like. The dielectric layer 122 may be formed by spin coating, lamination, CVD, the like, or a combination thereof.

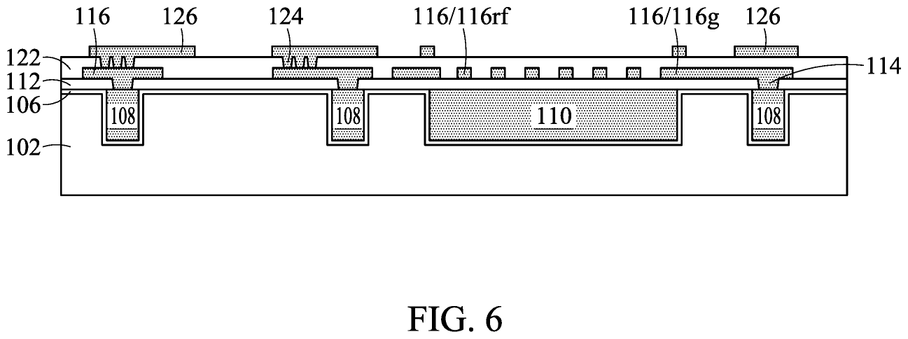

In FIG. 6, the dielectric layer 122 is then patterned to form openings exposing portions of the first metallization pattern 116. The patterning may be formed by an acceptable process, such as by exposing the dielectric layer 122 to light when the dielectric layer 122 is a photo-sensitive material or by etching using, for example, an anisotropic etch. If the dielectric layer 122 is a photo-sensitive material, the dielectric layer 122 can be developed after the exposure. Through vias 124 are formed in the openings through the dielectric layer 122 and a second metallization pattern 126 is formed over the dielectric layer 122. The through vias 124 and second metallization pattern 126 may be formed using processes and materials similar to those described above with respect to the through vias 114 and the first metallization pattern 116.

In FIG. 7, the dielectric layer 132 may be formed on the second metallization pattern 126 and the dielectric layer 122. In some embodiments, the dielectric layer 132 may be formed using processes and materials similar to those discussed above with respect to the dielectric layer 112 and/or dielectric layer 122. The dielectric layer 132 is then patterned to form openings exposing portions of the second metallization pattern 126. The patterning may be formed by an acceptable process, such as described above with respect to the dielectric layer 122. Through vias 134 are formed in the openings through the dielectric layer 132 and a third metallization pattern 136 is formed over the dielectric layer 132. The through vias 134 and third metallization pattern 136 may be formed using processes and materials similar to those described above with respect to the through vias 114 and the first metallization pattern 116. The third metallization pattern 136 includes a patch antenna 136a formed as part of the third metallization pattern 136.

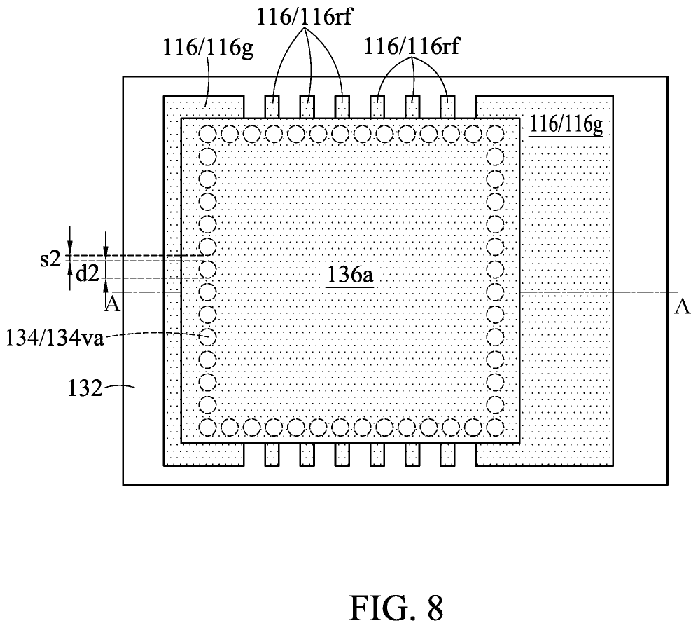

FIGS. 8 through 14 provide a modified top down view of a portion of the structure of FIG. 7 utilizing various options for a through via array 134va of the through vias 134 and a metal wall 126w of the second metallization pattern 126. The top down view of FIGS. 8 through 14 includes a top down view of the dashed box portion of the structure of FIG. 7. The ground metal 116g and metal grate 116rf would be covered by the dielectric layer 132, but are included in these views to show the relationships of each of the illustrated parts. In FIGS. 8 through 10A and 10B, the through via array 134va is shown in dashed outline as, it is actually below the antenna 136a. The antenna 136a is coupled by the through via array 134va to the metal wall 126w of the second metallization pattern 126.

As illustrated in FIG. 8, the through via array 134va may include multiple through vias arranged around a periphery of the footprint of the antenna 136a. Each of the through vias 134 is arranged in a single deep row of through vias 134. They are positioned close together so that the spacing s2 between each of the through vias of the through via array 134va is less than the diameter d2 or width of each of the through-vias. In some embodiments the spacing s2 is 20% to 50% of the width wl.

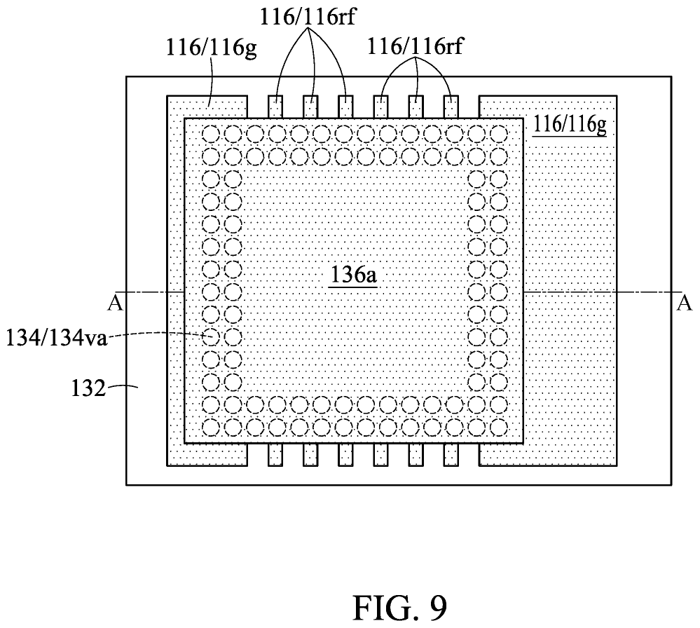

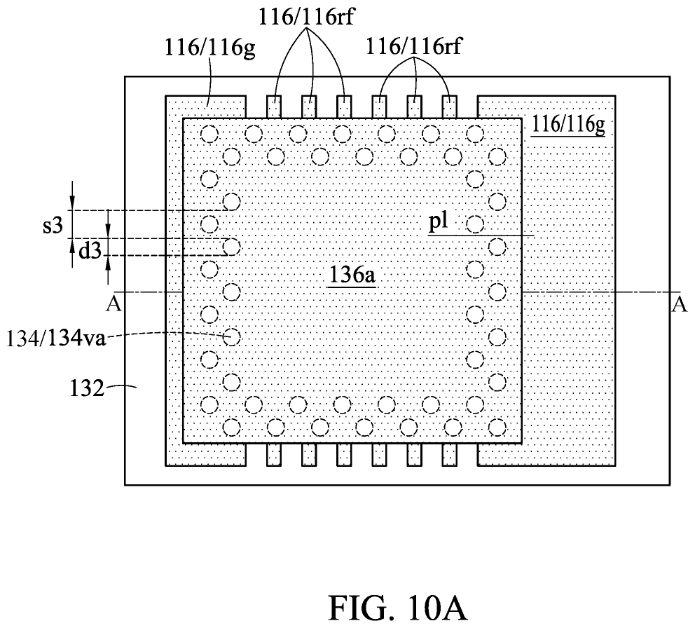

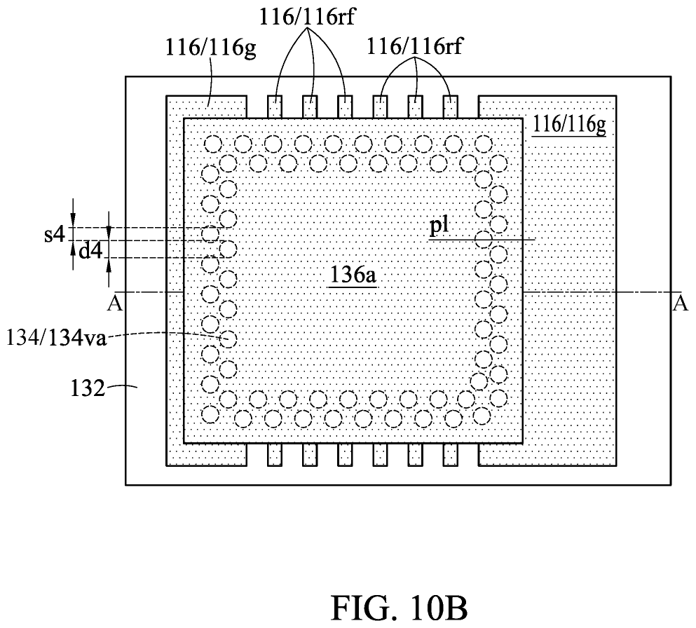

In FIG. 9, the through via array 134va may include a double deep row of through vias 134 aligned to the periphery of the antenna 136a. In some embodiments, the through via array 134va may include one or more additional rows of the through vias 134 on one or more of the sides of the antenna 136a. In some embodiments, the through vias 134 of the through via array 134va may each be horizontally and vertically aligned, such as illustrated in FIG. 9. In other embodiments, however, the through via array 134va may include multiple rows of staggered through vias 134, such as illustrated in FIGS. 10A and 10B.

In FIG. 10A, the staggered through vias 134 are separated in each row by a spacing s3 where s3 is greater than the diameter d3 of each of the through vias 134. As such, a line p1 perpendicular to the orientation of the through via array 134va (i.e., perpendicular to the edge direction of the antenna 136a) may fit between the staggered through vias 134 without contacting any of the through vias 134. In FIG. 10B, in accordance with some embodiments, the staggered through vias 134 are separated in each row by a spacing s4, where s4 is less than the diameter d4 of each of the through vias 134. As such, any line p1 perpendicular to the orientation of the through via array 134va would contact at least one of the through vias 134. The arrangement of the through via array 134va in FIG. 10B may be beneficial in helping the oscillation region operate more efficiently by causing more of the generated or received radio frequency signals to oscillate in the oscillation region.

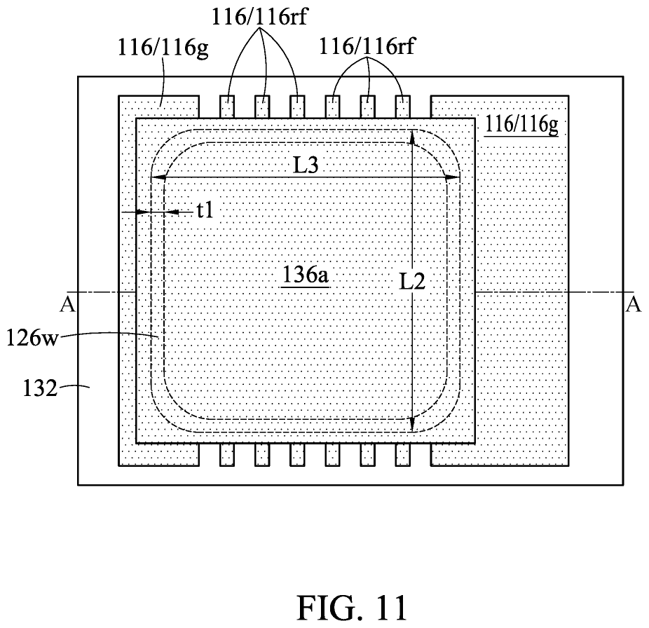

In FIGS. 11 through 14 a metal wall 126w is shown in dashed outline as, it is actually below the antenna 136a. The antenna 136a is coupled by the through via array 134va to the metal wall 126w of the second metallization pattern 126. In FIG. 11, the metal wall 126w is illustrated as being a single solid ring of metal aligned to the periphery of the antenna 136a. The metal wall 126w may be electrically coupled to the antenna 136a by the through via array 134va, while in other embodiments, the metal wall 126w may be electrically floating, i.e., not electrically coupled to the antenna 136a or another metal structure. The metal wall 126w and/or through via array 134va serves as an outer lateral boundary of the oscillation region. The length L2 of the metal wall 126w in a first horizontal dimension and the length L3 of the metal wall 126w in a second horizontal dimension may each be between about 10 μm and about 100,000 μm. The lateral thickness t1 of the metal wall 126w may be between about 0.1 μm and about 20 μm.

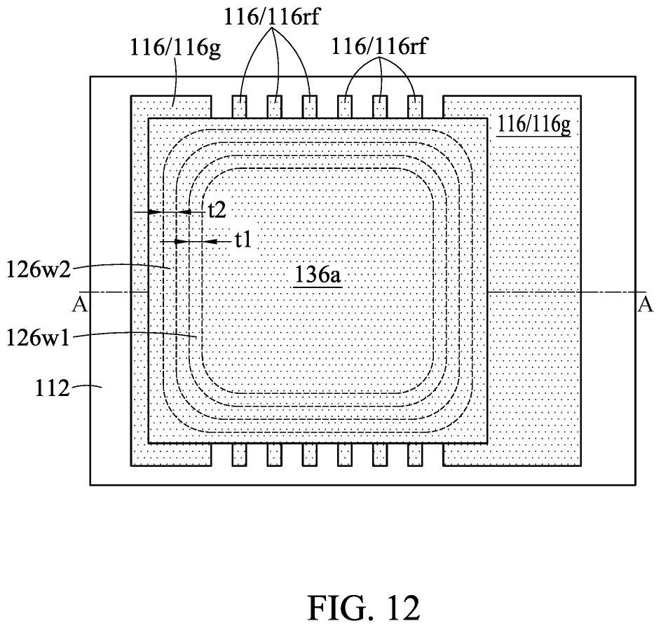

In FIG. 12, the metal wall structure includes a first metal wall 126w1 and a second metal wall 126w2 surrounding the first metal wall 126w1. In some embodiments, the first metal wall 126w1 may be separated from the second metal wall 126w2 by a distance between about 0.1 μm and about 100 μm. In some embodiments, the first metal wall 126w1 and second metal wall 126w2 may be combined with an embodiment including double deep through via array 134va, such as illustrated in FIGS. 9, 10A, and 10B, with one row of the through via array 134va coupled to the first metal wall 126wl and another row of the through via array 134va coupled to the second metal wall 126w2. In other embodiments, one or more of the first metal wall 126w1 and/or second metal wall 126w2 may be electrically floating, i.e., not electrically coupled to the antenna 136a or another metal structure. In some embodiments, additional metal walls 126wx may be provided in like manner as the first metal walls 126w1 and second metal walls 126w2. The lateral thickness t1 of the first metal wall 126w1 may be between about 0.1 μm and about 20 μm, and the lateral thickness t2 of the second metal wall 126w2 may be between about 0.1 μm and about 20 μm. The lateral thickness t1 may be the same or different than the lateral thickness t2.

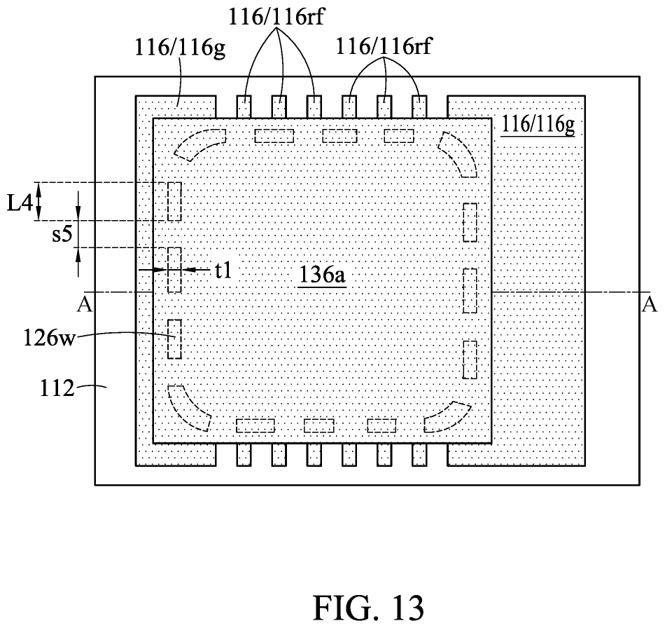

In FIG. 13, the metal wall 126w is segmented. Instead of extending continuously around the antenna 136a footprint, the metal wall 126w has breaks disposed along its length. In some embodiments, the spacing s5 between one end of one segment and the nearest end of an adjacent segment may be between about 0.1 μm and about 20 μm. In some embodiments, the length L4 of each of the segments may be between about 1 μm and about 1000 μm. The lengths and spacing may be standard to all the segments of the metal wall 126w or may vary from segment to segment and space to space. The lateral thickness t1 of the metal wall 126w may be between about 0.1 μm and about 20 μm.

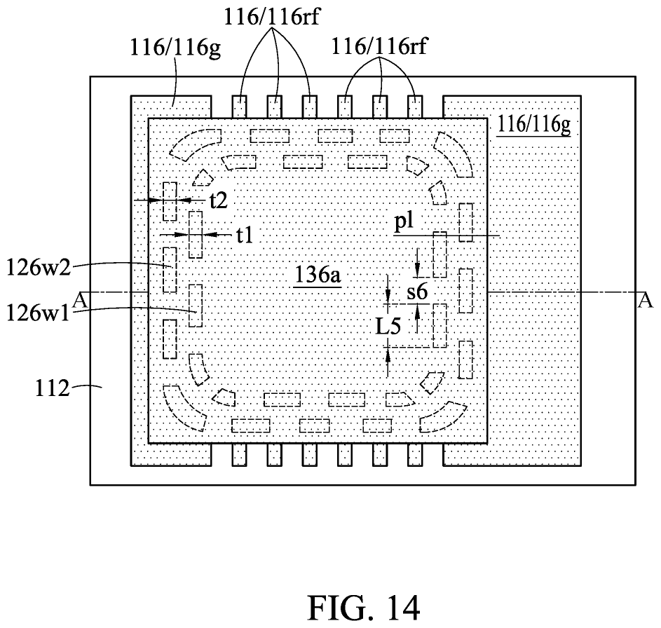

In FIG. 14, the metal wall structure includes a first metal wall 126w1 and a second metal wall 126w2 surrounding the first metal wall 126wl. Each of the first metal wall 126w1 and second metal wall 126w2 may be segmented like the metal wall 126w of FIG. 13. In some embodiments, the segments may be aligned. In other embodiments, such as illustrated in FIG. 14, the segments may be staggered such that a line p1 perpendicular to the edge of the antenna 136a would intersect the first metal wall 126wl and/or the second metal wall 126w2. In such embodiments, the spacing s6 between segments may be smaller than the length L5 of the segments. In some embodiments, the spacing s6 between one end of one segment and the nearest end of an adjacent segment may be between about 0.1 μm and about 20 μm. In some embodiments, the length L5 of each of the segments may be between about 1 μm and about 1000 μm. The lengths and spacing may be standard to all the segments of the metal wall 126w or may vary from segment to segment and space to space. The lateral thickness t1 of the first metal wall 126w1 may be between about 0.1 μm and about 20 μm, and the lateral thickness t2 of the second metal wall 126w2 may be between about 0.1 μm and about 20 μm. The lateral thickness t1 may be the same or different than the lateral thickness t2.

The metal walls 126w or metal wall structures including first metal walls 126w1 and second metal walls 126w2 and so forth of FIGS. 11 through 14 and the through via array 134va of FIGS. 8 through 10A and 10B together provide an oscillation region. A line perpendicular to the edge of the antenna 136a may intersect the metal walls 126w, 126wl, and/or 126w2 (depending on the design used). If such a line, for example, were representative of a radio signal transmitting from or receiving to the antenna 136a, the signal would reflect off of the first metal wall 126w1 and/or second metal wall 126w2 and oscillate between sides of the metal walls. In oscillating, the signals received or transmitted can be additive, causing a signal boost before being received by the antenna 126a (as in the case of a received signal) or leaving the oscillation region, propagating away from the antenna 126a (as in the case of transmitting a signal). The oscillation may also be similarly aided by the many individual and potentially overlapping through vias 134 of the through via array 134va.

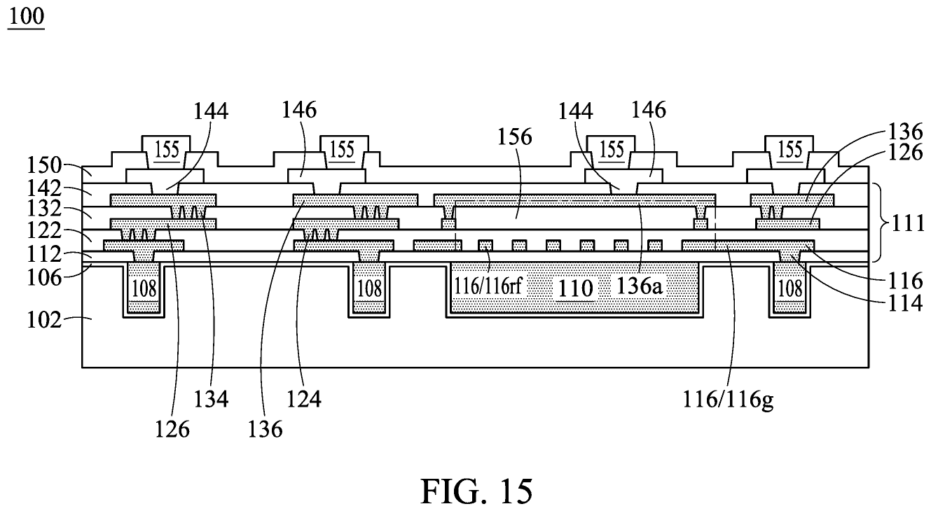

In FIG. 15, after the third metallization pattern 136 is formed, a dielectric layer 142 is formed over the third metallization pattern 136. The dielectric layer 142 may be formed using processes and materials similar to those used to form the dielectric layer 112. The dielectric layer 142 is then patterned to form openings exposing portions of the third metallization pattern 136, including the antenna 136a. The patterning may be formed by an acceptable process, such as described above with respect to the dielectric layer 122. Through vias 144 are formed in the openings through the dielectric layer 142 and a fourth metallization pattern 146 is formed over the dielectric layer 142. In some embodiments, the through vias 144 and fourth metallization pattern 146 may be formed using processes and materials similar to those described above with respect to the through vias 114 and the first metallization pattern 116. In other embodiments, the through vias 144 and fourth metallization pattern 146 may be formed using materials alternate to those used to form the through vias 114 and first metallization pattern 116. For example, the through vias 144 and fourth metallization pattern 146 may be formed of aluminum using a seed layer, photoresist, and plating process such as described above. Utilizing aluminum for example, may provide desired physical and electrical properties between the subsequently formed connectors 155 and the material of the redistribution structure 111. For example, the fourth metallization pattern 146 may be thicker than the metallization patterns of the redistribution structure 111 and produce less diffusion of conductive materials into the surrounding dielectric layers and passivation layer 150.

Following the formation of the through vias 144 and fourth metallization pattern 146, the passivation layer 150 may be formed over the fourth metallization pattern 146 to protect the fourth metallization pattern from further processing. The passivation layer 150 may be formed of any suitable material, such as silicon nitride, silicon oxynitride, silicon oxycarbonitride, silicon carbide, polyimide, the like, or combinations thereof. After the passivation layer 150 is formed, openings corresponding to the connectors 155 may be made through the passivation layer 150 to expose portions of the fourth metallization pattern 146 through the passivation layer 150.

Connectors 155 are formed for connection to an integrated circuit device subsequently attached to the redistribution structure 111 by the fourth metallization pattern 146. The connectors 155 may be microbumps, having bump portions on and extending along the major surface of the passivation layer 150 and via portions extending through the passivation layer 150 to physically and electrically couple the fourth metallization pattern 146. As a result, the connectors 155 are electrically coupled to features of the redistribution structure 111 and one or more of the connectors 155 are coupled through the redistribution structure 111 to the metal fill 108. The connectors 155 may be formed of the same material as the fourth metallization pattern 146 or third metallization pattern 136.

In some embodiments, the connectors 155 may include an underbump metallization (UBM) and conductive connector on the UBM. The conductive connector of the connectors 155 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The connectors 155 may include a conductive material such as solder, copper, aluminum, gold, nickel, silver, palladium, tin, the like, or a combination thereof. In some embodiments, the connectors 155 are formed by forming a layer of solder over the UBMs through evaporation, electroplating, printing, solder transfer, ball placement, or the like. Once a layer of solder has been formed on the UBMs, a reflow may be performed in order to shape the material into the desired bump shapes. In another embodiment, the connectors 155 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

Following the formation of the connectors 155, the first package component 100 is formed. The first package component 100 includes an oscillation region 156, such as outlined by the dashed box illustrated in FIG. 15. The oscillation region 156 causes RF signals entering the metal grate 116rf or leaving the antenna 136a to bounce within the oscillation region 156, for example off of the through via array 134va, off of the metal grate 116rf, off the antenna 136a, and off the metal wall 126w, the RF signals adding and boosting their signals.

As noted above, the first package component 100 may be formed in a wafer and may be one of multiple first package components 100 formed in the wafer, each one of the first package components corresponding to first package region, a second package region, etc. Following the formation of the first package components 100, in some embodiments the first package components 100 may be singulated from one another in a singulation process. In other embodiments, integrated circuit dies may be mounted to the first package components 100 prior to singulation. The singulation process may be performed by sawing along scribe line regions, e.g., between the first package region (as illustrated in FIG. 15) and an adjacent second package region. The sawing singulates the first package component 100 from the adjacent first package component 100. The resulting, singulated first package component contains the corresponding package region and may then be used to attach appropriate dies and used in further processing. In some embodiments, the singulation process is performed after the integrated circuit dies 50 are attached to the first package component 100.

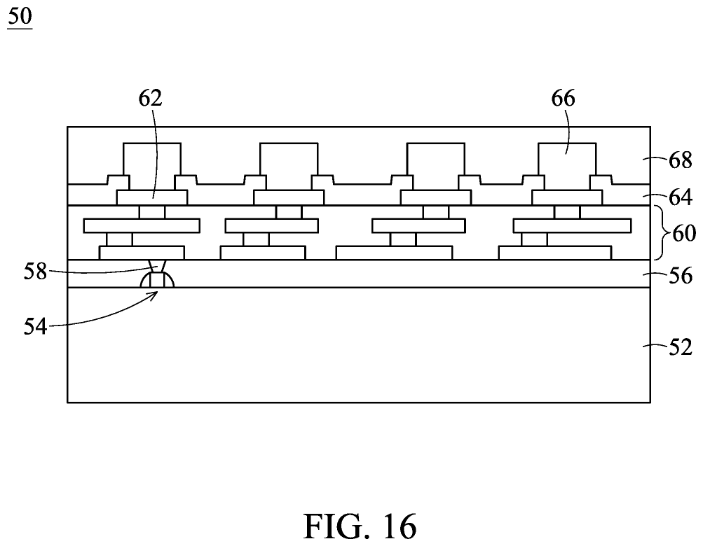

FIG. 16 illustrates a cross-sectional view of an integrated circuit die 50 in accordance with some embodiments. The integrated circuit die 50 will be packaged in subsequent processing to form an integrated circuit package. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) transmit/receiving die, an RF Baseband (BB) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 16), sometimes called a front side, and an inactive surface (e.g., the surface facing downwards in FIG. 16), sometimes called a back side.

Devices (represented by a transistor) 54 may be formed at the front surface of the semiconductor substrate 52. The devices 54 may be active devices (e.g., transistors, diodes, etc.), capacitors, resistors, etc. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 58 extend through the ILD 56 to electrically and physically couple the devices 54. For example, when the devices 54 are transistors, the conductive plugs 58 may couple the gates and source/drain regions of the transistors. Source/drain region(s) may refer to a source or a drain, individually or collectively dependent upon the context. The conductive plugs 58 may be formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. The interconnect structure 60 may be formed by, for example, metallization patterns in dielectric layers on the ILD 56. The metallization patterns include metal lines and vias formed in one or more low-k dielectric layers. The metallization patterns of the interconnect structure 60 are electrically coupled to the devices 54 by the conductive plugs 58.

The integrated circuit die 50 further includes pads 62, such as aluminum pads, to which external connections are made. The pads 62 are on the active side of the integrated circuit die 50, such as in and/or on the interconnect structure 60. One or more passivation films 64 are on the integrated circuit die 50, such as on portions of the interconnect structure 60 and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. The die connectors 66 may be formed by, for example, plating, or the like. The die connectors 66 electrically couple the respective integrated circuits of the integrated circuit die 50.

Optionally, solder regions (e.g., solder balls or solder bumps) may be disposed on the pads 62. The solder balls may be used to perform chip probe (CP) testing on the integrated circuit die 50. CP testing may be performed on the integrated circuit die 50 to ascertain whether the integrated circuit die 50 is a known good die (KGD). Thus, only integrated circuit dies 50, which are KGDs, undergo subsequent processing and are packaged, and dies, which fail the CP testing, are not packaged. After testing, the solder regions may be removed in subsequent processing steps.

A dielectric layer 68 may (or may not) be on the active side of the integrated circuit die 50, such as on the passivation films 64 and the die connectors 66. The dielectric layer 68 laterally encapsulates the die connectors 66, and the dielectric layer 68 is laterally coterminous with the integrated circuit die 50. Initially, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may bury the solder regions as well. Alternatively, the solder regions may be removed prior to forming the dielectric layer 68.

The dielectric layer 68 may be a polymer such as PBO, PI, BCB, or the like; a nitride such as silicon nitride or the like; an oxide such as silicon oxide, PSG, BSG, BPSG, or the like; the like, or a combination thereof. The dielectric layer 68 may be formed, for example, by spin coating, lamination, chemical vapor deposition (CVD), or the like. In some embodiments, the die connectors 66 are exposed through the dielectric layer 68 during formation of the integrated circuit die 50. In some embodiments, the die connectors 66 remain buried and are exposed during a subsequent process for packaging the integrated circuit die 50. Exposing the die connectors 66 may remove any solder regions that may be present on the die connectors 66.

In some embodiments, the integrated circuit die 50 is a stacked device that includes multiple semiconductor substrates 52. For example, the integrated circuit die 50 may be a memory device such as a hybrid memory cube (HMC) module, a high bandwidth memory (HBM) module, or the like that includes multiple memory dies. In such embodiments, the integrated circuit die 50 includes multiple semiconductor substrates 52 interconnected by through-substrate vias (TSVs). Each of the semiconductor substrates 52 may (or may not) have an interconnect structure 60.

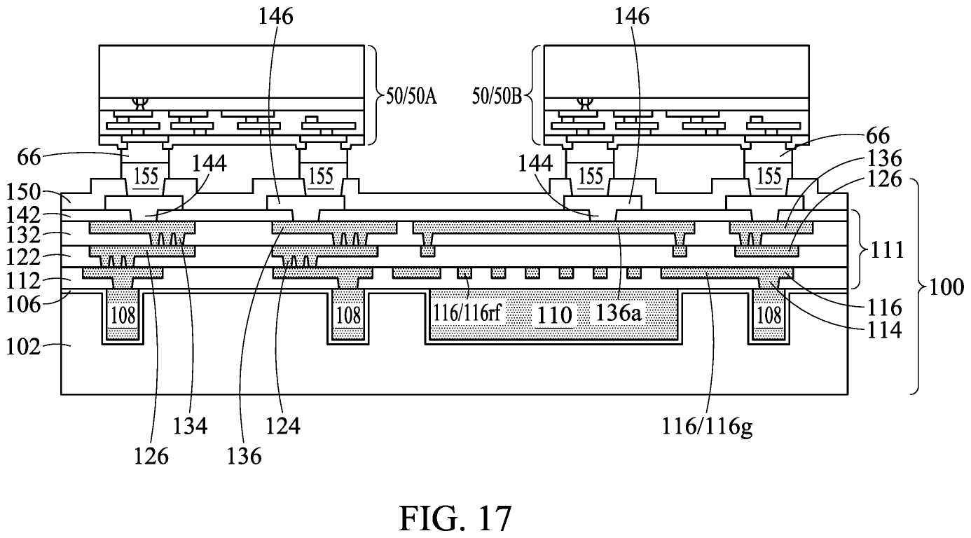

In FIG. 17, integrated circuit dies 50 (e.g., a first integrated circuit die 50A and a second integrated circuit die 50B) are connected to the connectors 155. A desired type and quantity of integrated circuit dies 50 are adhered in each of the package regions corresponding to each of the first package components 100. In the embodiment shown, multiple integrated circuit dies 50 are connected adjacent one another, including the first integrated circuit die 50A and the second integrated circuit die 50B in each of the package regions. The first integrated circuit die 50A may be a logic device, such as a central processing unit (CPU), a graphics processing unit (GPU), a system-on-a-chip (SoC), a microcontroller, or the like. In one embodiment, the first integrated circuit die 50A is a SoC with Baseband (BB) RF functions for RF signal processing, such as 5G/6G RF signals. The second integrated circuit die 50B may be a memory device, such as a dynamic random access memory (DRAM) die, a static random access memory (SRAM) die, a hybrid memory cube (HMC) module, a high bandwidth memory (HBM) module, or the like. In one embodiment, the second integrated circuit die 50B may be a transmitting/receiving (tx/rx) die which is coupled to the antenna 136a. Additional integrated circuit dies 50 with any of the aforementioned functionality may also attached as desired. The first integrated circuit die 50A and second integrated circuit die 50B may be formed in processes of a same technology node, or may be formed in processes of different technology nodes. For example, the first integrated circuit die 50A may be of a more advanced process node than the second integrated circuit die 50B. The first and second integrated circuit dies 50A and 50B may have different sizes (e.g., different heights and/or surface areas), or may have the same size (e.g., same heights and/or surface areas).

The integrated circuit dies 50 may be attached using any suitable process, such as a pick and place process to align the die connectors 66 with the connectors 155 and couple the die connectors 66 to the connectors 155 using a die attachment process, such as reflowing a solder material to adhere the die connectors 66 to the connectors 155. Other die attachment processes may be used, such as utilizing a direct metal to metal bond between the connectors 66 and the connectors 155. In some embodiments, the connectors 155 have an epoxy flux formed thereon before they are reflowed with at least some of the epoxy portion of the epoxy flux remaining after the first and second integrated circuit dies 50A and 50B are attached to the first package component 100.

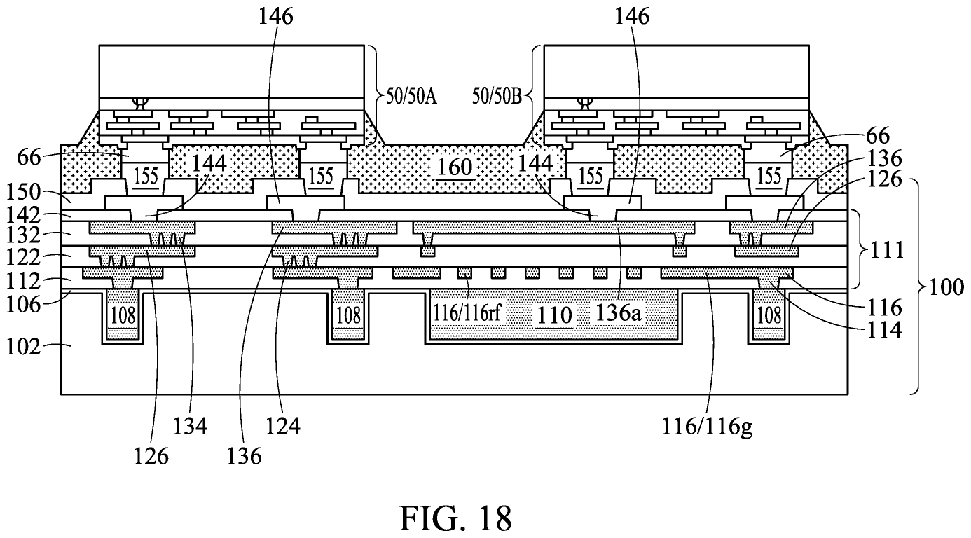

In FIG. 18, an underfill 160 is formed between the first package component 100 and the first integrated circuit die 50A and the second integrated circuit die 50B, surrounding the connectors 155 and connectors 66. The underfill 160 may reduce stress and protect the joints resulting from the reflowing of the connectors 155. The underfill 160 may be formed by a capillary flow process after the first and second integrated circuit dies 50A and 50B are attached. In embodiments where the epoxy flux is formed, it may act as the underfill. As seen in FIG. 18, in some embodiments, the underfill 160 may extend at least partially up a sidewall of the first and second integrated circuit dies 50A and 50B. In some embodiments, the underfill 160 may continue to extend all the way to the uppermost surface (i.e., the backsides of the first and second integrated circuit dies 50A and 50B). In such embodiments, the upper surface of the underfill 160 may dip down between the first and second integrated circuit dies 50A and 50B in a manner similar to that illustrated in FIG. 18.

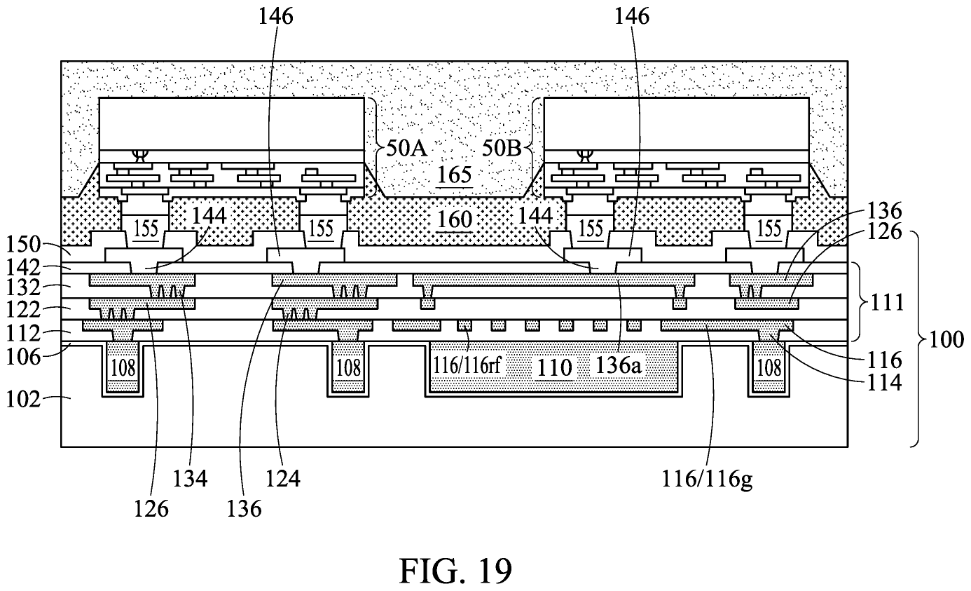

In FIG. 19, an encapsulant 165 is formed on and around the various components, including on and around the underfill 160 and on and around the first and second integrated circuit dies 50A and 50B. After formation, the encapsulant 165 encapsulates the first and second integrated circuit dies 50A and 50B. The encapsulant 165 may be a molding compound, epoxy, or the like. The encapsulant 165 may be applied by compression molding, transfer molding, or the like, and may be formed over the underfill 160 such that the first and second integrated circuit dies 50A and 50B are buried or covered. The encapsulant 165 is further formed in gap regions between the first and second integrated circuit dies 50A and 50B. The encapsulant 165 may be applied in liquid or semi-liquid form and then subsequently cured.

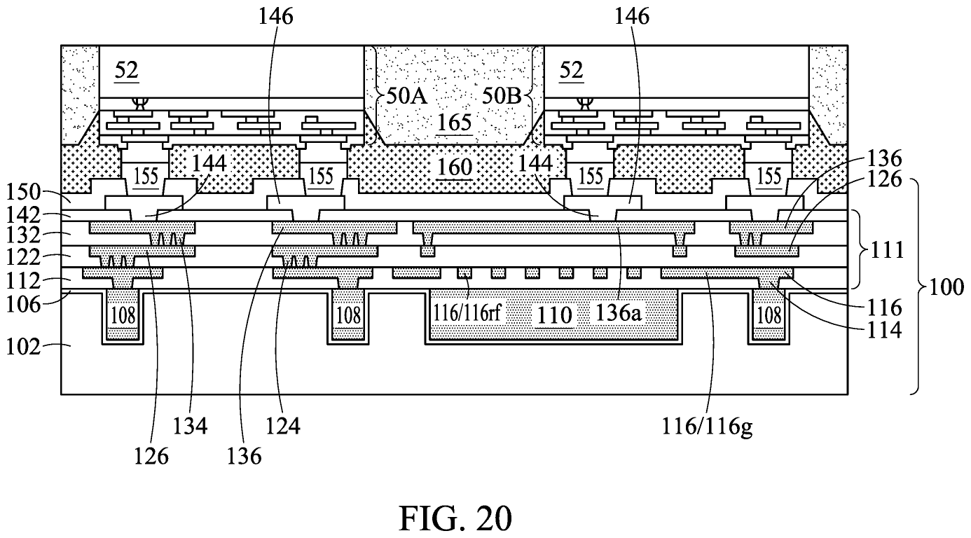

In FIG. 20, a planarization process is performed on the encapsulant 165 to expose the back side of the first and second integrated circuit dies 50A and 50B. In some embodiments, the planarization process may continue to operate to thin the substrate 52 of the first and second integrated circuit dies 50A and 50B. Top surfaces of the first and second integrated circuit dies 50A and 50B and encapsulant 165 are substantially coplanar after the planarization process within process variations. The planarization process may be, for example, a chemical-mechanical polish (CMP), a grinding process, or the like.

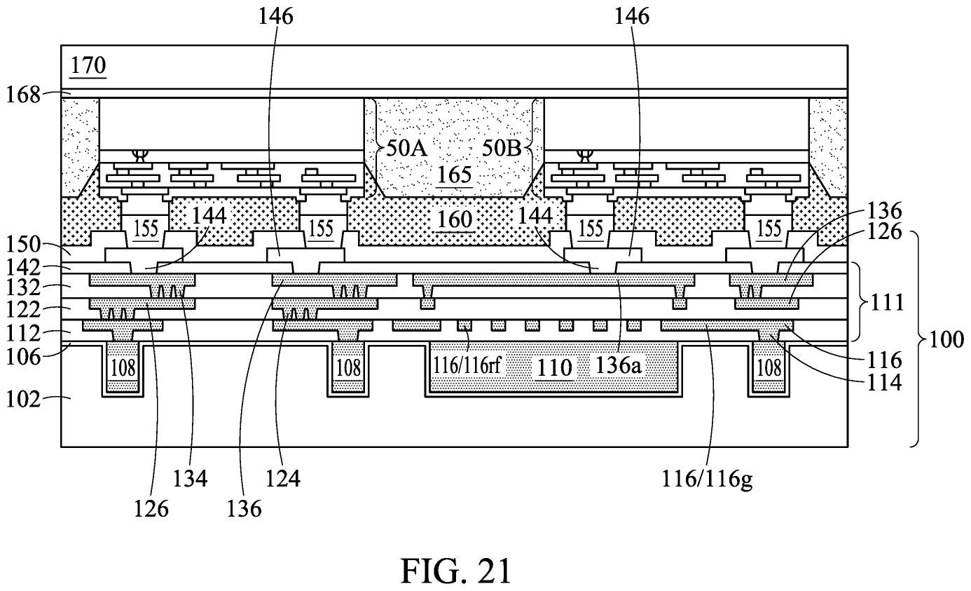

In FIG. 21, a carrier substrate 170 is mounted to the upper side of the structure of FIG. 20 by a release layer 168. The carrier substrate 170 may be a glass carrier substrate, a ceramic carrier substrate, or the like. The release layer 168 may be formed of a polymer-based material, which may be removed along with the carrier substrate 170 in subsequent steps. In some embodiments, the release layer 168 is an epoxy-based thermal-release material, which loses its adhesive property when heated, such as a light-to-heat-conversion (LTHC) release coating. In other embodiments, the release layer 168 may be an ultra-violet (UV) glue, which loses its adhesive property when exposed to UV lights. The release layer 168 may be dispensed as a liquid and cured, may be a laminate film laminated onto the carrier substrate 170 or the encapsulant 165 and first and second integrated circuit dies 50A and 50B, or may be the like. The top surface of the release layer 168 may be leveled and may have a high degree of planarity.

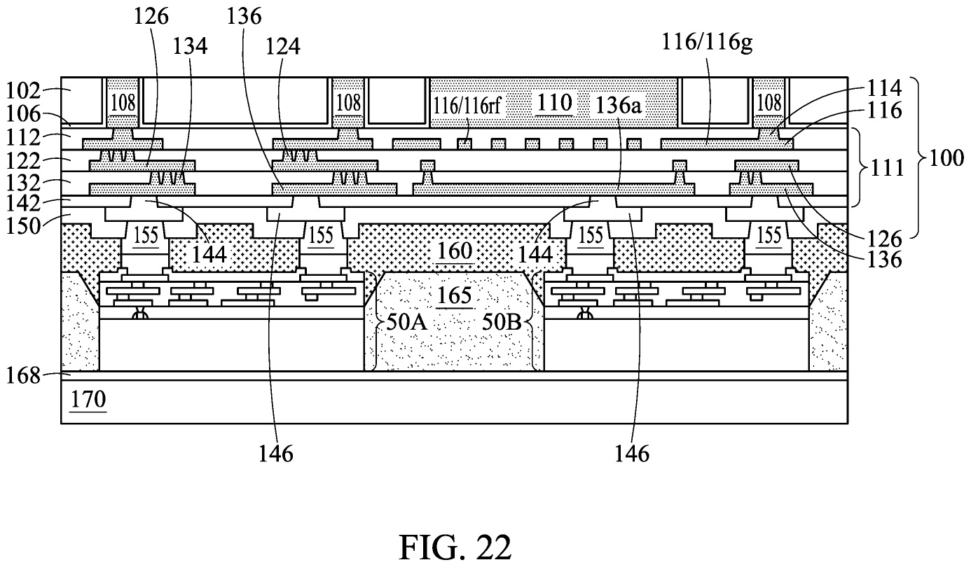

In FIG. 22, the structure of FIG. 21 is flipped over and the substrate 102 is thinned to expose the metal fills 108 and 110. The thinning process may be a grinding process, a CMP process, an etching process, or combinations thereof. Following the thinning process, a portion of the liner layer 106 is removed which was previously along a bottom of the metal fills 108 and 110, along with a portion of the substrate 102. In some embodiments, some of the metal fill 108 and/or metal fill 110 may be removed, for example, if the metal fill 108 or metal fill 110 was thicker than the other.

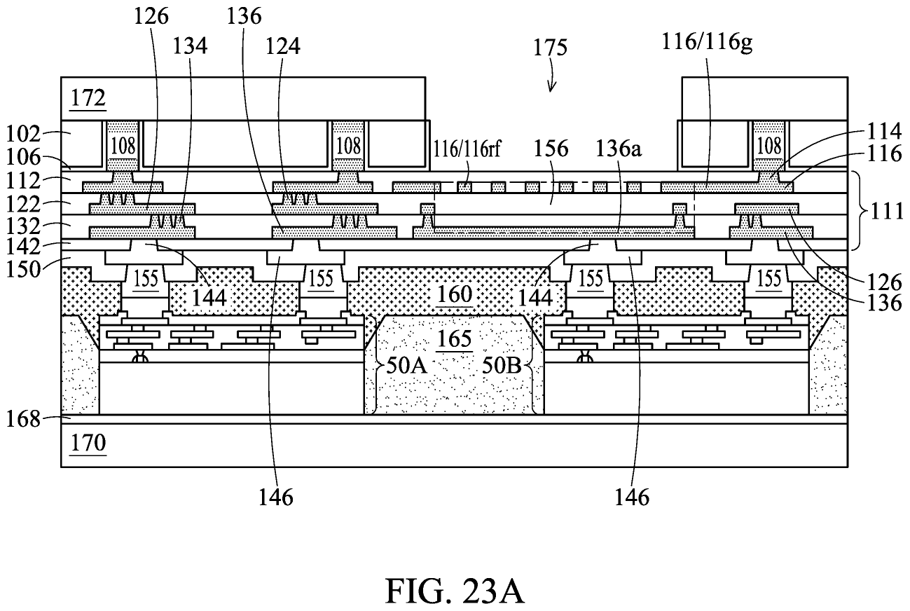

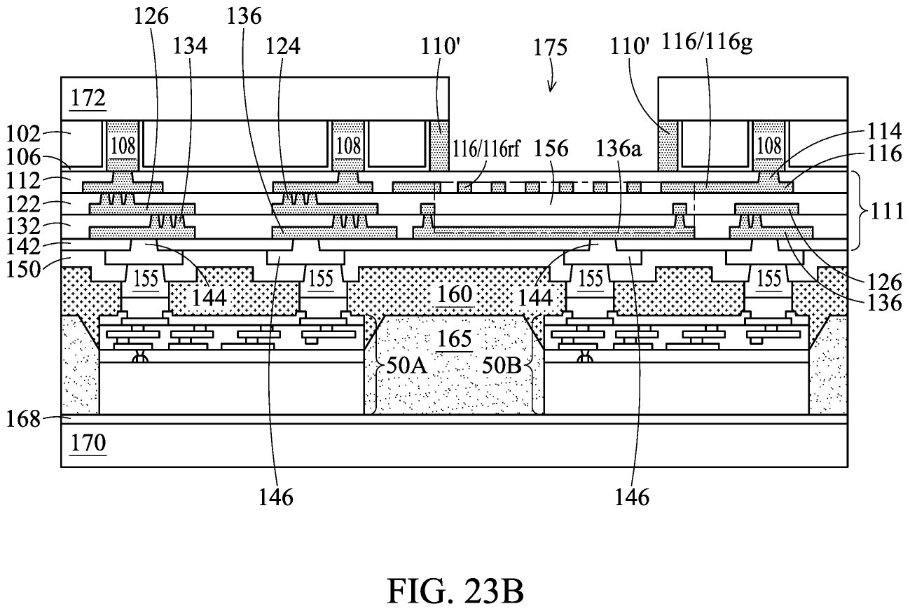

In FIG. 23A, a photomask 172 is formed over the substrate 102 and patterned to form an opening corresponding to the metal fill 110. Then the metal fill 110 is etched to form a cavity 175 in the substrate 102 corresponding to the antenna 136a. Because RF signals do not easily propagate through metal or semiconductor materials, the cavity 175 is made in the semiconductor substrate 102 to allow the RF signals in and out of the oscillation region 156.

In FIG. 23B, the photomask 172 is formed over the substrate 102 and patterned to form an opening over the metal fill 110. In FIG. 23B, however, the photomask 172 is smaller than the metal fill 110 but as large as the metal grate 116rf. Thus, when the metal fill 110 is etched to form the cavity 175 in the substrate 102, the cavity 175 may have a portion 110′ of the metal fill 110 remaining on side walls of the cavity 175.

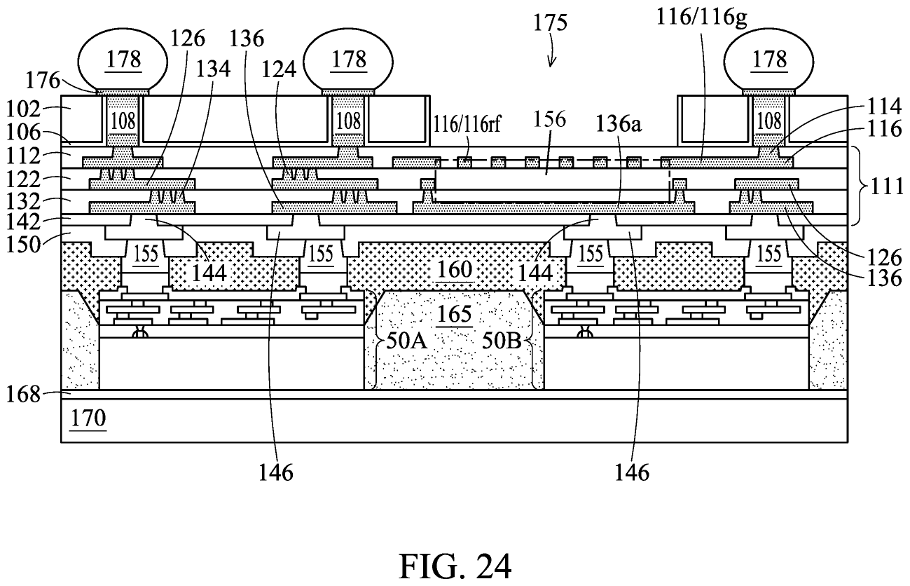

In FIG. 24, the photomask 172 is removed by an acceptable process, such as by an ashing process. Then, conductive connectors 178 are formed over the metal fills 108 which serve as through vias for the substrate 102. In some embodiments bond pads 176 may be formed first over the metal fills 108. The bond pads 176 are electrically coupled to the metal fill 108, the redistribution structure 111, and the first and/or second integrated circuit dies 50A and 50B.

The bond pads 176 may be formed using similar processes and materials used to form the first metallization pattern 116. In some embodiments, the bond pads 176 are formed by forming recesses (not shown) into a dielectric layer (not shown) disposed on the substrate 102. The recesses may be formed to allow the bond pads 176 to be embedded into the dielectric layer. In other embodiments, the recesses are omitted as the bond pads 176 may be formed on the dielectric layer or on the substrate 102. In some embodiments, the bond pads 176 include a thin seed layer (not shown) made of copper, titanium, nickel, gold, palladium, the like, or a combination thereof. The conductive material of the bond pads 176 may be deposited over the thin seed layer. The conductive material may be formed by an electro-chemical plating process, an electroless plating process, CVD, atomic layer deposition (ALD), PVD, the like, or a combination thereof. In an embodiment, the conductive material of the bond pads 176 is copper, tungsten, aluminum, silver, gold, the like, or a combination thereof.

In some embodiments, the bond pads 176 are UBMs that include three layers of conductive materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the bond pads 176. Any suitable materials or layers of material that may be used for the bond pads 176 are fully intended to be included within the scope of the current application.

Conductive connectors 178 are formed on the bond pads 176. The conductive connectors 178 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 178 may include a conductive material such as solder, copper, aluminum, gold, nickel, silver, palladium, tin, the like, or a combination thereof. In some embodiments, the conductive connectors 178 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 178 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

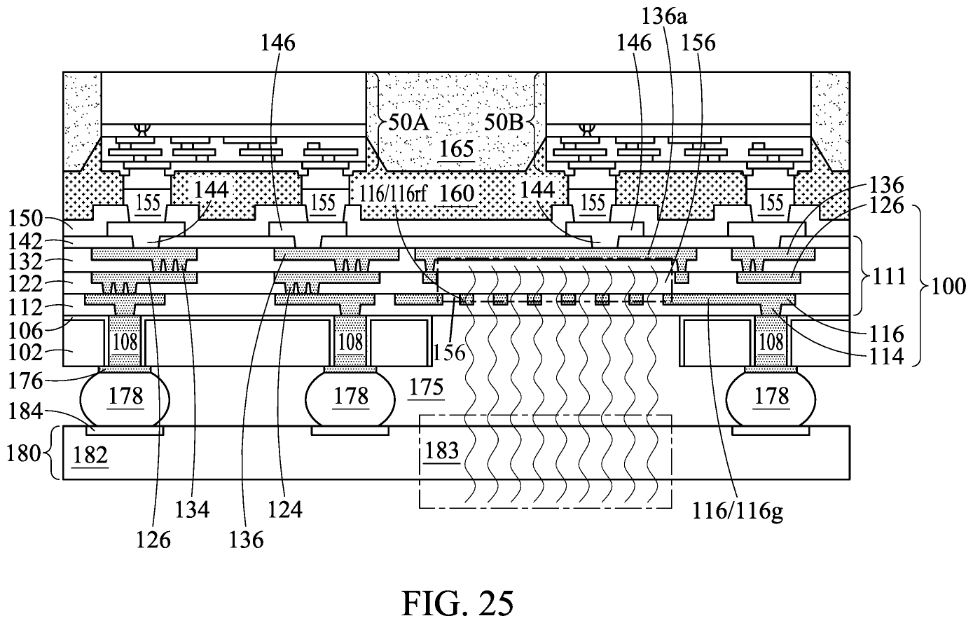

In FIG. 25, a carrier substrate de-bonding is performed to detach (or “de-bond”) the carrier substrate 170 from the top of the structure, e.g., the encapsulant 165 and first and second integrated circuit dies 50A and 50B. In accordance with some embodiments, the de-bonding includes projecting a light such as a laser light or an UV light on the release layer 168 so that the release layer 168 decomposes under the heat of the light and the carrier substrate 170 can be removed.

In embodiments where the first package component 100 was not previously singulated, the first package component 100, including the first and second integrated circuit dies 50A and 50B may be singulated from neighboring package components. The singulation process described above may be used to perform the singulation.

The structure is then flipped over and attached by the conductive connectors 178 to a package substrate 180 using the conductive connectors 178. The package substrate 180 includes a substrate core 182 and bond pads 184 over the substrate core 182. The substrate core 182 may be made of a non-metal or non-semiconductor material, such as an organic material, such as BT resin (bismaleimide triazine resin), a build-up ABF resin, or MIS (molded interconnect substrate) material, or the like. The substrate core 182 is, in one alternative embodiment, based on an insulating core such as a fiberglass reinforced resin core. One example core material is fiberglass resin such as FR4. The substrate core 182 may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core 182 may also include metallization layers and vias (not shown), with the bond pads 184 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 182 is substantially free of active and passive devices.

The package substrate 180 may have a keep out zone 183 aligned to the substrate cavity 175 and oscillation region 156, to allow the passage of RF signals to and from the antenna 136a without interference from conductive or semi-conductive materials.

In some embodiments, the conductive connectors 178 are reflowed to attach the conductive connectors 178 to the bond pads 184. The conductive connectors 178 electrically and/or physically couple the package substrate 180, including metallization layers in the substrate core 182, to the conductive elements of the first package component 100 and first and second integrated circuit dies 50A and 50B.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

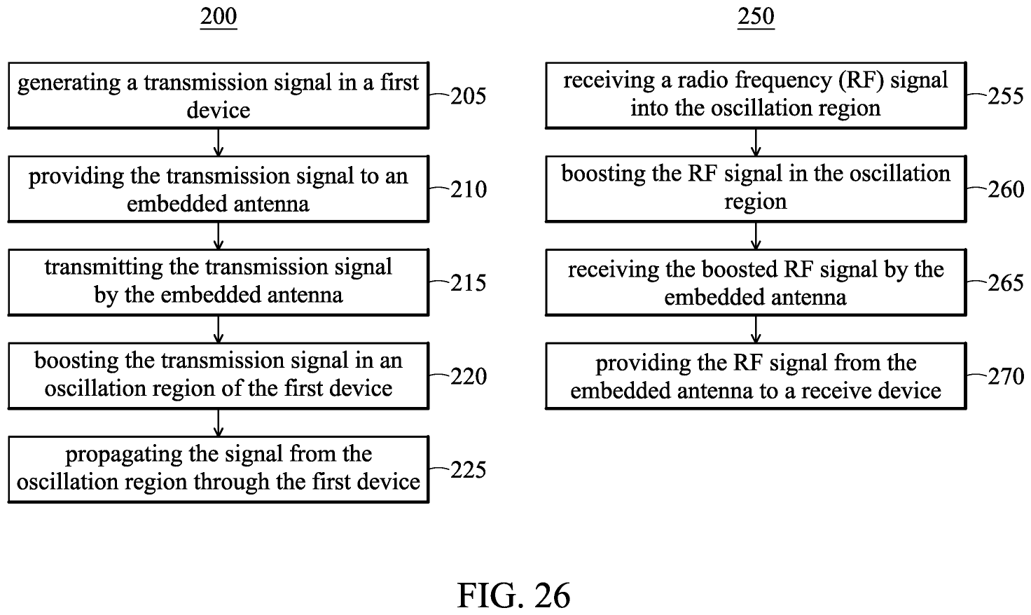

FIG. 26 illustrates a flow diagram for a process 200 and a flow diagram for a process 250. In the process 200 at the first element 205, a transmission signal is generated in a first device, such as the second integrated device die 50B. At 210, the transmission signal is provided to an embedded antenna, such as the antenna 136a. At 215, the transmission signal is transmitted by the embedded antenna. At 220, the transmission signal is boosted in an oscillation region of the first device, such as the oscillation region 156. At 225 the signal is propagated from the oscillation region through the first device, for example beyond the metal grate 116rf. In the process 250 at the first element 255, an RF signal is received into an oscillation region of a first device, such as the oscillation region 256. At 260, the RF signal is boosted in the oscillation region. At 265, the boosted RF signal is received by an embedded antenna, such as the embedded antenna 136a. At 270 the RF signal is provided from the embedded antenna to a receive device, such as the second integrated circuit die 50B.

Embodiments of FIGS. 1-26 may achieve advantages. Embodiments provide an oscillation region for an embedded antenna. The oscillation region provides a better transmitted signal or received signal for the embedded antenna, which is suitable for 5G and/or 6G signals and their associated RF signal frequency ranges (e.g., for the upcoming 5th Gen. (5.8 GHz) and 5th Gen. high frequency (29˜38 GHz and 77˜120 GHz) RF transceiver). Given the simplified embedding processes, these devices are suitable for use in highly integrated devices, such as portable, wearable, internet of things (IoT), and smart phone products. Embedding the antenna in a metallization layer and providing an oscillation region aligned to the antenna provides the ability to utilize an embedded antenna at the same production cost as without. Yet the embedded antenna cavity shrinks the footprint normally needed to utilize an embedded antenna, which must typically be walled off from the rest of the structure. The thicknesses of the various layers may be tuned for specific application and to meet packaging requirements.

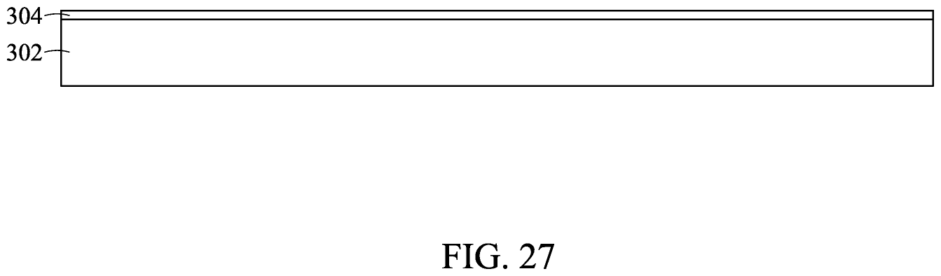

FIGS. 27 through 44 illustrate cross-sectional views of intermediate steps during a process for forming a dual band antenna component 300, in accordance with some embodiments. The illustrated views in FIGS. 27 through 43 are of but one package region of what may be several package regions of a workpiece. The integrated circuit packages may also be referred to as integrated fan-out (InFO) packages.

In FIG. 27, a carrier substrate 302 is provided, and a release layer 304 is formed on the carrier substrate 302. The carrier substrate 302 may be a glass carrier substrate, a ceramic carrier substrate, or the like. The carrier substrate 302 may be a wafer, such that multiple packages can be formed on the carrier substrate 302 simultaneously.

The release layer 304 may be formed of a polymer-based material, which may be removed along with the carrier substrate 302 from the overlying structures that will be formed in subsequent steps. In some embodiments, the release layer 304 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 304 may be dispensed as a liquid and cured, may be a laminate film laminated onto the carrier substrate 302, or may be the like. The top surface of the release layer 304 may be leveled and may have a high degree of planarity.

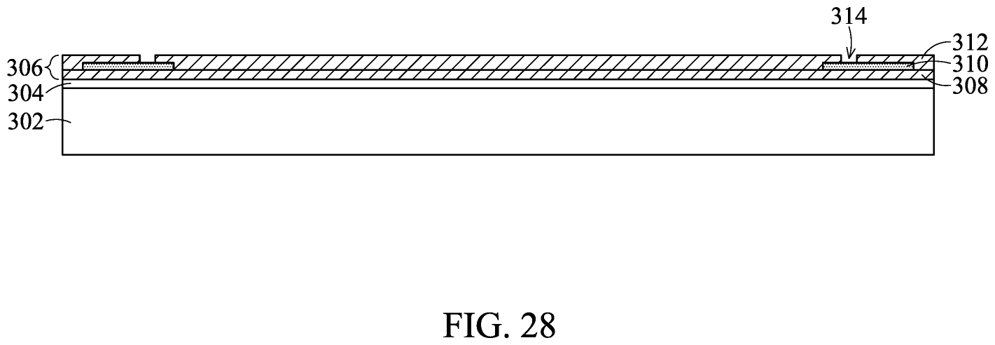

In FIG. 28, a back-side redistribution structure 306 may be formed on the release layer 304. In the embodiment shown, the back-side redistribution structure 306 includes a dielectric layer 308, a metallization pattern 310 (sometimes referred to as redistribution layers or redistribution lines), and a dielectric layer 312. The back-side redistribution structure 306 is optional. In some embodiments, a dielectric layer without metallization patterns is formed on the release layer 304 in lieu of the back-side redistribution structure 306.

The dielectric layer 308 may be formed on the release layer 304. The bottom surface of the dielectric layer 308 may be in contact with the top surface of the release layer 304. In some embodiments, the dielectric layer 308 is formed of a polymer, such as PBO, PI, BCB, or the like. In other embodiments, the dielectric layer 308 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 308 may be formed by any acceptable deposition process, such as spin coating, CVD, laminating, the like, or a combination thereof.

The metallization pattern 310 may be formed on the dielectric layer 308. The formation of the metallization pattern 310 may be by any suitable process. It should be understood also that any of the metallization patterns discussed herein may be formed using any suitable process, such as the one described here.

As an example to form metallization pattern 310, a seed layer is formed over the dielectric layer 308. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist (not shown) is then formed and patterned on the seed layer. The photoresist may be formed by spin coating or the like and may be exposed to light for patterning. The pattern of the photoresist corresponds to the metallization pattern 310. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern 310.

The dielectric layer 312 may be formed on the metallization pattern 310 and the dielectric layer 308. In some embodiments, the dielectric layer 312 may be omitted. In some embodiments, the dielectric layer 312 is formed of a polymer, which may be a photo-sensitive material such as PBO, PI, BCB, or the like, that may be patterned using a lithography mask. In other embodiments, the dielectric layer 312 is formed of a nitride such as silicon nitride; an oxide such as silicon oxide, PSG, BSG, BPSG; or the like. The dielectric layer 312 may be formed by spin coating, lamination, CVD, the like, or a combination thereof. The dielectric layer 312 is then patterned to form openings 314 exposing portions of the metallization pattern 310. The patterning may be formed by an acceptable process, such as by exposing the dielectric layer 312 to light when the dielectric layer 312 is a photo-sensitive material or by etching using, for example, an anisotropic etch. If the dielectric layer 312 is a photo-sensitive material, the dielectric layer 312 can be developed after the exposure.

FIG. 28 illustrates a redistribution structure 306 having a single metallization pattern 310 for illustrative purposes. In some embodiments, the back-side redistribution structure 306 may include any number of dielectric layers and metallization patterns. If more dielectric layers and metallization patterns are to be formed, steps and processes discussed above may be repeated. The metallization patterns may include one or more conductive elements. The conductive elements may be formed during the formation of the metallization pattern by forming the seed layer and conductive material of the metallization pattern over a surface of the underlying dielectric layer and in the opening of the underlying dielectric layer, thereby interconnecting and electrically coupling various conductive lines.

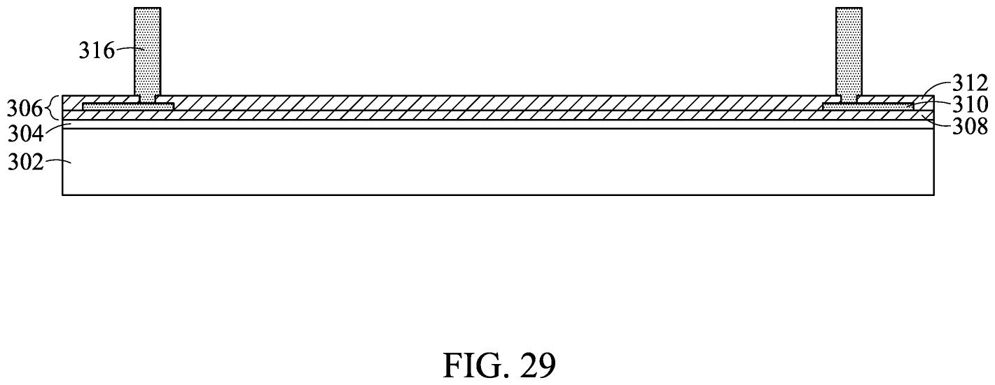

In FIG. 29, through vias 316 are formed in the openings 314 and extending away from the topmost dielectric layer of the back-side redistribution structure 306 (e.g., the dielectric layer 312). As an example to form the through vias 316, a seed layer (not shown) is formed over the back-side redistribution structure 306, e.g., on the dielectric layer 312 and portions of the metallization pattern 310 exposed by the openings 314. In some embodiments, the seed layer is a metal layer, which may be a single layer or a composite layer comprising a plurality of sub-layers formed of different materials. In a particular embodiment, the seed layer comprises a titanium layer and a copper layer over the titanium layer. The seed layer may be formed using, for example, PVD or the like. A photoresist is formed and patterned on the seed layer. The photoresist may be formed by spin coating or the like and may be exposed to light for patterning. The pattern of the photoresist corresponds to conductive vias. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the through vias 316.

As another example to form the through vias 316, a photoresist layer (not shown) may be deposited over the back-side redistribution structure 306, e.g., on the dielectric layer 312 and portions of the metallization pattern 310 exposed by the openings 314. The photoresist layer may then be patterned using acceptable techniques to form openings corresponding to the placement of the through vias 316. The openings expose a portion of the metallization pattern 310, for example, by way of the openings 314. Then, a seed layer (not shown) may be formed over the photoresist layer and in the openings of the photoresist layer, including on an upper surface of the metallization pattern 310. The seed layer is a metal layer, which may be a single layer or a composite layer comprising a plurality of sub-layers formed of different materials. The seed layer may comprise a titanium layer and a copper layer over the titanium layer. The seed layer may be formed using, for example, PVD or the like. A conductive material is formed in the openings of the photoresist layer and over the photoresist layer on the seed layer. The conductive material may be formed by plating, such as electroplating or electroless plating, or the like. The conductive material may comprise a metal, like copper, titanium, tungsten, aluminum, or the like. The photoresist is removed, which also results in the removal of the portions of the seed layer and conductive material over the photoresist. The photoresist may be removed by an acceptable ashing or stripping process, such as using an oxygen plasma or the like. The remaining portions of the seed layer (for example on the bottom and sidewalls of the through vias 316) and conductive material form the through vias 316.

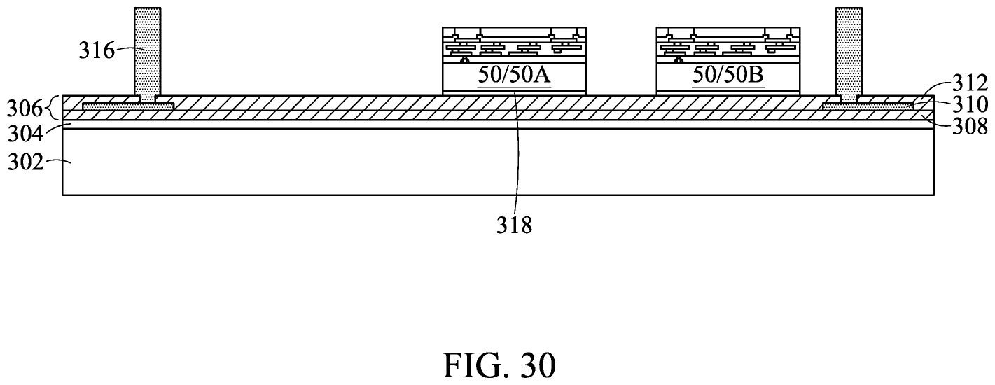

In FIG. 30, integrated circuit dies 50 (e.g., a first integrated circuit die 50A and a second integrated circuit die 50B) are adhered to the dielectric layer 312 or dielectric layer 308 by an adhesive 318. In the embodiment shown, multiple integrated circuit dies 50 are adhered adjacent one another, including the first integrated circuit die 50A and the second integrated circuit die 50B. The first integrated circuit die 50A and second integrated die 50B may each be any of the listed dies above, such as described with respect to FIG. 16. In one embodiment, the first integrated circuit die 50A is a RF transmit/receive die configured to transmit and receive at 12.4 GHz nominal range for 4G/5G and the second integrated circuit die 50B is an RF transmit/receive die configured to transmit and receive at the 77 GHz nominal range (e.g., 76-77 GHz) for 6G and automotive radar sensor systems (e.g., for driver assistance sensor technologies). Additional dies may also be used which are not illustrated. Notably, a space is left open to provide a clear transmission/reception path to an antenna which is subsequently formed. The first integrated circuit die 50A and second integrated circuit die 50B may be formed in processes of a same technology node, or may be formed in processes of different technology nodes. For example, the first integrated circuit die 50A may be of a more advanced process node than the second integrated circuit die 50B. The integrated circuit dies 50A and 50B may have different sizes (e.g., different heights and/or surface areas), or may have the same size (e.g., same heights and/or surface areas).

The adhesive 318 is on back-sides of the integrated circuit dies 50 and adheres the integrated circuit dies 50 to the back-side redistribution structure 306, such as to the dielectric layer 312. The adhesive 318 may be any suitable adhesive, epoxy, die attach film (DAF), or the like. The adhesive 318 may be applied to back-sides of the integrated circuit dies 50, may be applied over the surface of the carrier substrate 302 if no back-side redistribution structure 306 is utilized, or may be applied to an upper surface of the back-side redistribution structure 306 if applicable. For example, the adhesive 318 may be applied to the back-sides of the integrated circuit dies 50 before singulating to separate the integrated circuit dies 50.

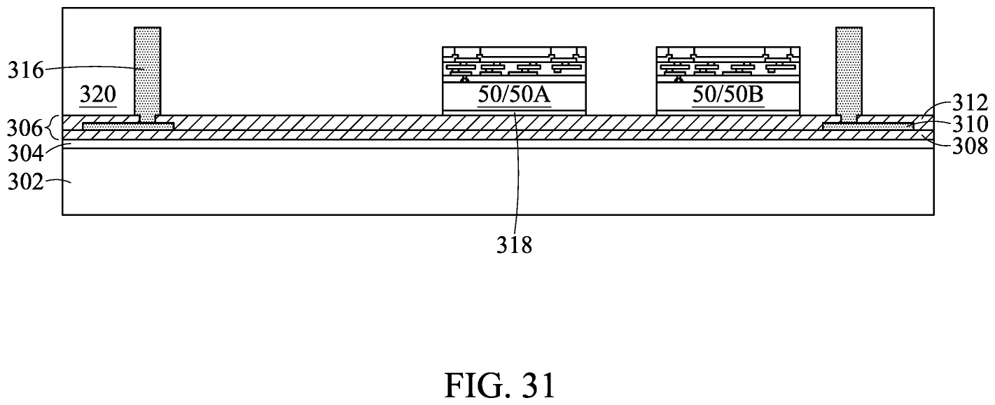

In FIG. 31, an encapsulant 320 is formed on and around the various components. After formation, the encapsulant 320 encapsulates the through vias 316 and integrated circuit dies 50. The encapsulant 320 may be glass (SiO₂), spin-on-glass (SiO₂), ceramics, alumina (Al₂O₃), sapphire, polymer (PBO, BTX, PI), resin, epoxy, molding compounds, or the like. The encapsulant 320 may include a base material, which may be a polymer, a resin, an epoxy, or the like, and filler particles in the base material. The filler particles may be spherical. The filler particles may be dielectric particles of silica, alumina, boron nitride, or the like. The encapsulant 320 may be applied by compression molding, transfer molding, or the like, and may be formed over the carrier substrate 302 such that the through vias 316 and/or the integrated circuit dies 50 are buried or covered. The encapsulant 320 is further formed in gap regions between the integrated circuit dies 50. The encapsulant 320 may be applied in liquid or semi-liquid form and then subsequently cured.

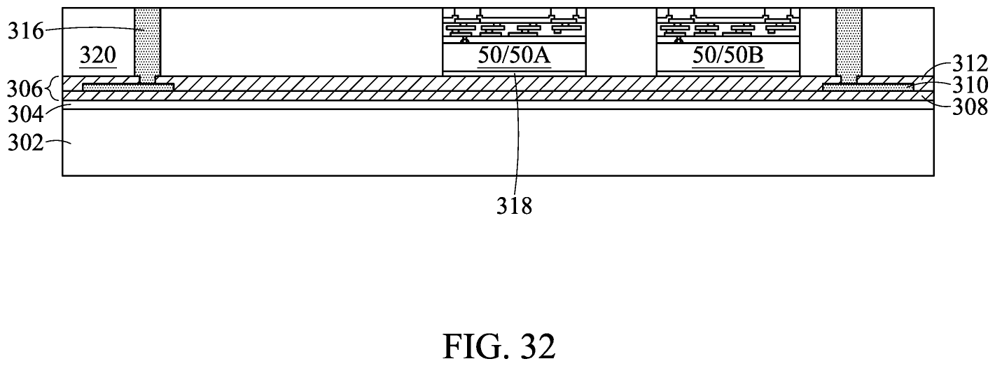

In FIG. 32, a planarization process is performed on the encapsulant 320 to expose the through vias 316 and the die connectors 66 (see FIG. 16). The planarization process may also remove material of the through vias 316, dielectric layer 68 (see FIG. 16), and/or die connectors 66 until the die connectors 66 and through vias 316 are exposed. Top surfaces of the through vias 316, die connectors 66, dielectric layer 68, and encapsulant 320 are substantially coplanar after the planarization process within process variations. The planarization process may be, for example, a chemical-mechanical polish (CMP), a grinding process, or the like. In some embodiments, the planarization may be omitted, for example, if the through vias 316 and/or die connectors 66 are already exposed.

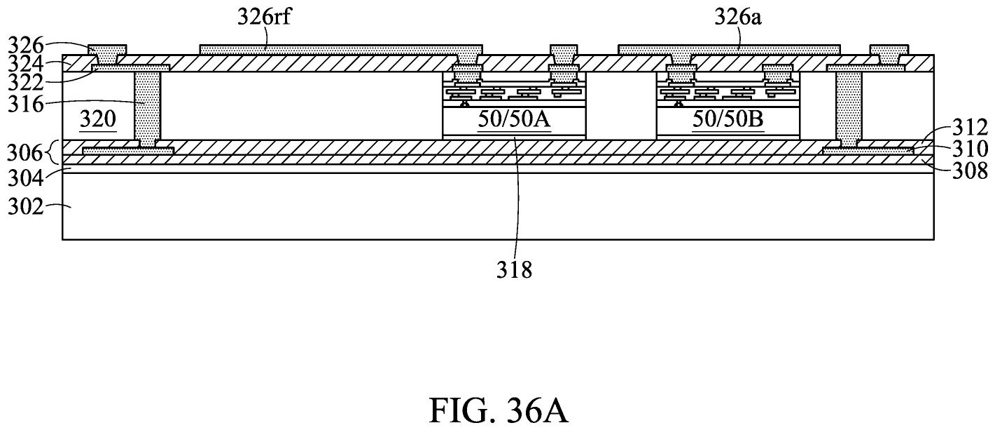

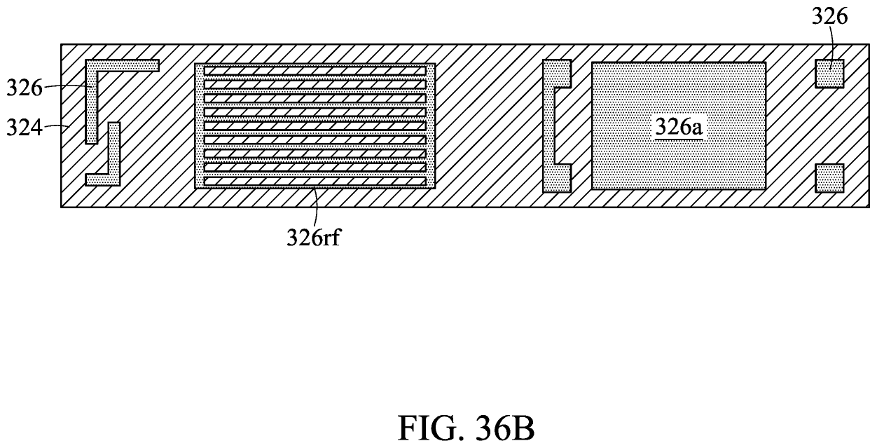

The thickness of the encapsulant 320 is configurable based on the desired thickness and need for the final package. The through vias 316, for example, may be made to be between 100 μm and 2 mm tall. As such, the thickness of the encapsulant can also be between about 100 μm and 2 mm. Because the placement of the high-frequency antenna (326a of FIG. 36A) is outward facing and transmits/receives away from the encapsulant 320, the thickness of the encapsulant 320 does not interfere with the high-frequency antenna.

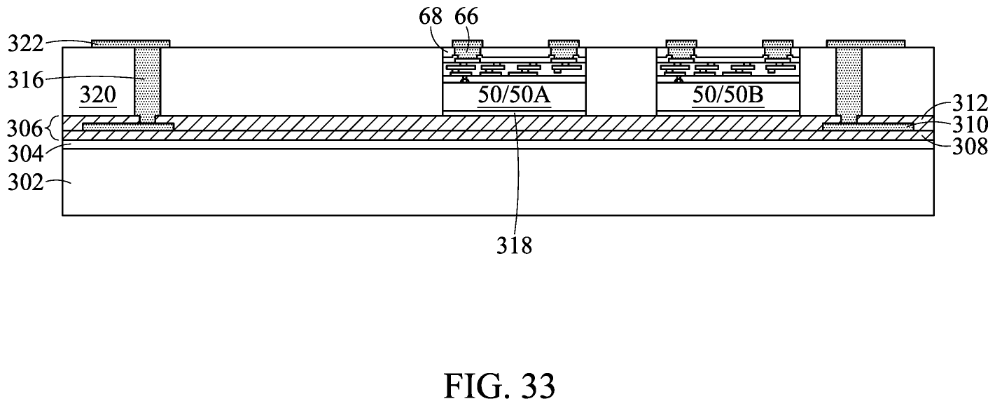

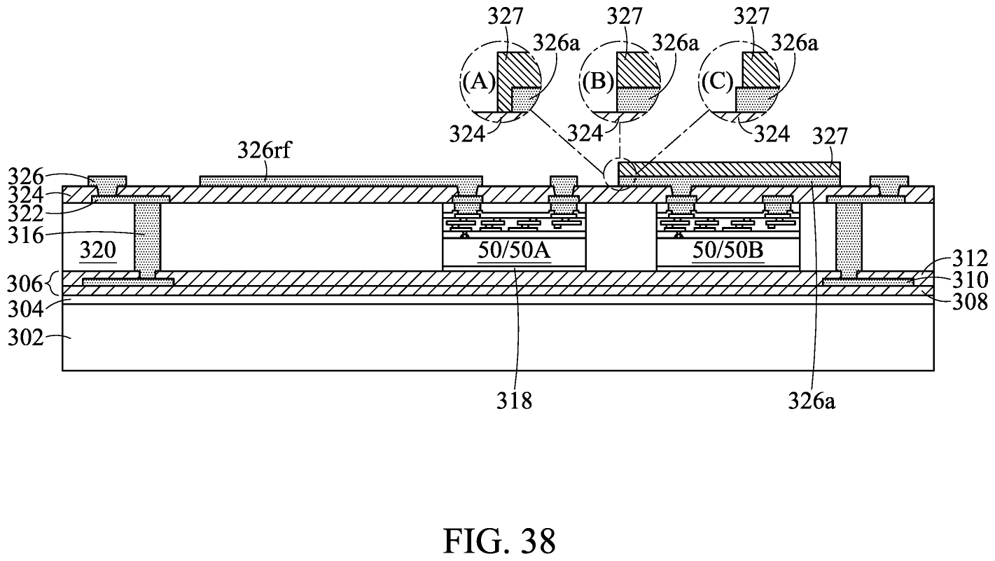

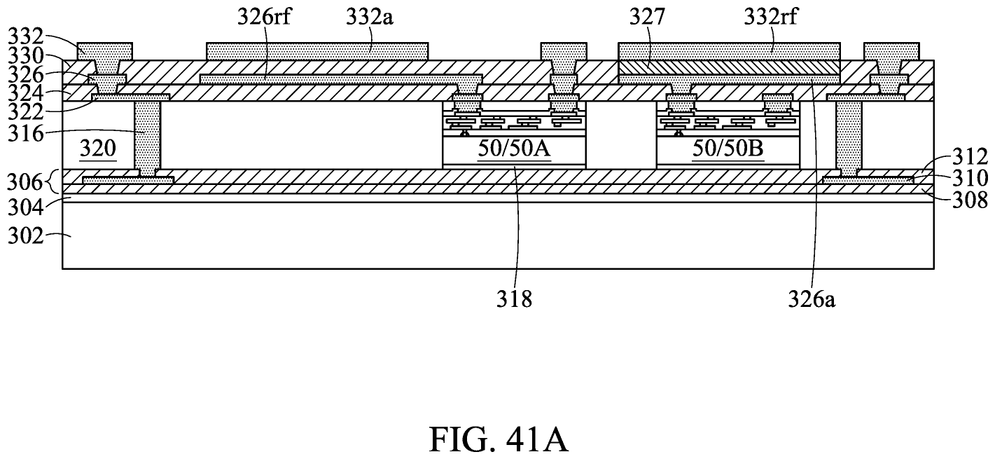

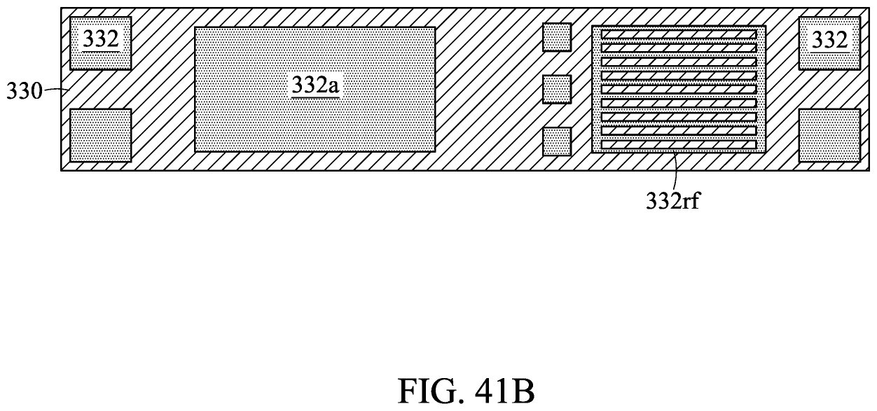

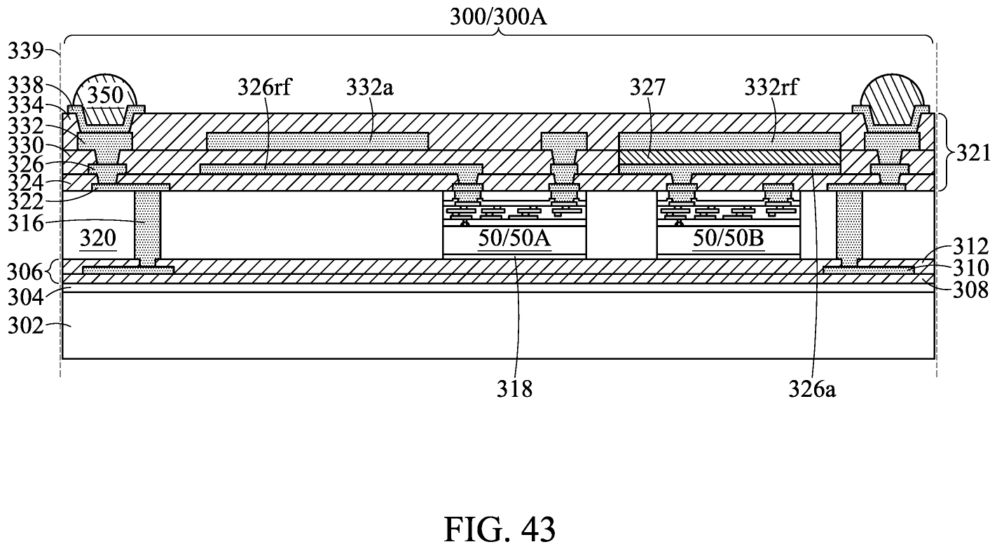

In FIGS. 33, 34, 35, 36A, 36B, 37, 38, 39, 40, 41A, 41B, and 43, a front-side redistribution structure 322 (see FIG. 41) is formed over the encapsulant 320, through vias 316, and integrated circuit dies 50, the front-side redistribution structure 122 including a first integrated antenna (antenna 332a of FIG. 41A) and a second integrated antenna (antenna 326a of FIG. 36A), as well as a high-k zone or high-k region (high-k zone 327 of FIG. 38) aligned to the second integrated antenna, such as described below. In the illustrated embodiments, the front-side redistribution structure 322 includes dielectric layers 324, 330, and 334; and metallization patterns 322, 328, and 330. Some of the metallization patterns are functional to provide signal grating and/or signal transmission/reception. The metallization patterns may also be referred to as redistribution layers or redistribution lines. The front-side redistribution structure 322 is shown as an example having three layers of metallization patterns. More or fewer dielectric layers and metallization patterns may be formed in the front-side redistribution structure 322. For example, the structure 300′ of FIG. 43 has four layers of metallization patterns. If fewer dielectric layers and metallization patterns are to be formed, steps and process discussed below may be omitted. If more dielectric layers and metallization patterns are to be formed, steps and processes discussed below may be repeated.

In FIG. 33, the metallization pattern 322 is formed. In some embodiments, an under-dielectric layer may be formed prior to forming the metallization pattern 322 and then the metallization pattern 322 is formed over the under-dielectric layer, with portions extending through the under-dielectric layer to contact the through vias 316 and die connectors 66. In the illustrated embodiments, however, the metallization pattern 322 includes conductive elements extending along the major surface of the encapsulant 320, and along the upper surfaces of the through vias 316, the die connectors 66, and the dielectric layer 68. The metallization pattern 322 may be formed using processes and materials similar to those used to form the metallization pattern 310.

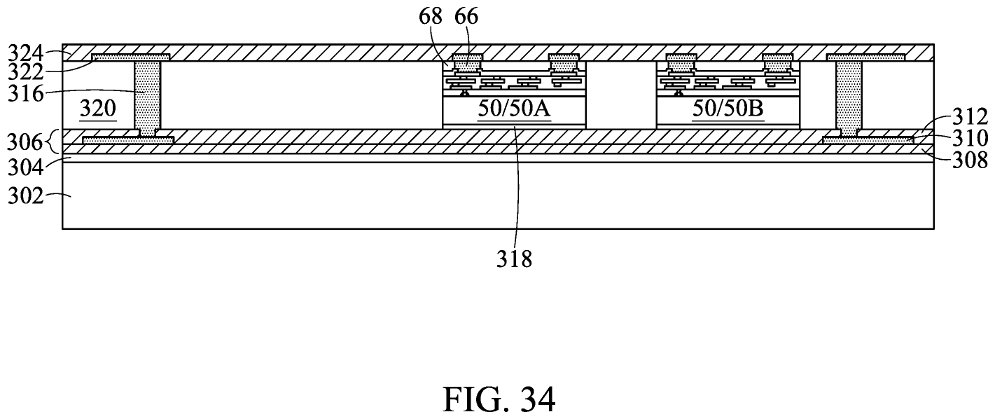

In FIG. 34, the dielectric layer 324 is then formed. The dielectric layer 324 is deposited on the encapsulant 320 and, in the illustrated example, on the metallization pattern 322. The dielectric layer 324 may also contact the through vias 316, the die connectors 66, and/or the dielectric layer 68. In some embodiments, the dielectric layer 324 is formed of a photo-sensitive material such as PBO, PI, BCB, or the like, which may be patterned using a lithography mask The dielectric layer 324 may be formed by spin coating, lamination, CVD, the like, or a combination thereof.

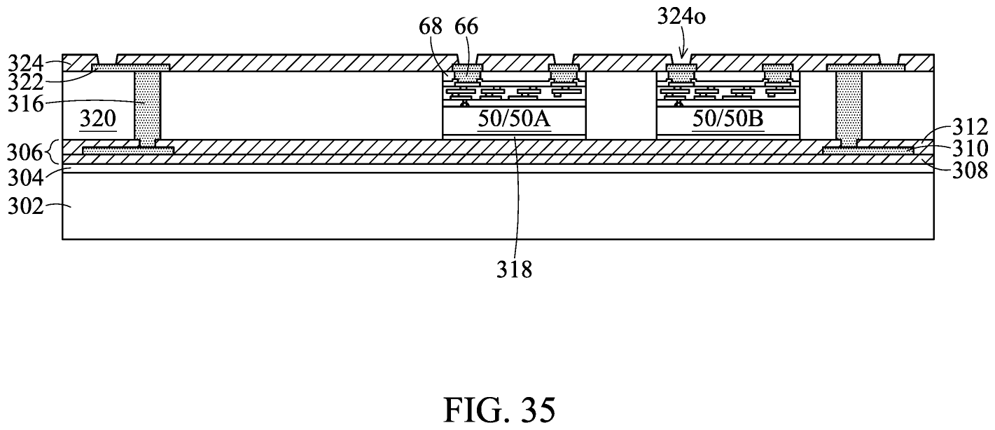

In FIG. 35, the dielectric layer 324 is patterned. The patterning of the dielectric layer 324 forms openings 324o exposing portions of the metallization pattern 322. The patterning may be by an acceptable process, such as by exposing and developing the dielectric layer 324 to light when the dielectric layer 324 is a photo-sensitive material or by etching using, for example, an anisotropic etch. If an under-dielectric layer is used, it may be formed and patterned in like manner.

In FIGS. 36A and 36B, the metallization pattern 326 is formed. FIG. 36A is a cross-sectional view continuing from FIG. 35. FIG. 36B is a top down view of a portion of the structure of FIG. 36A. The metallization pattern 326 includes portions on and extending along the major surface of the dielectric layer 324. The metallization pattern 326 further includes portions extending through the openings 324o of the dielectric layer 324 to physically and electrically couple the metallization pattern 322. The metallization pattern 326 may be formed in a similar manner and of a similar material as the metallization pattern 322. In some embodiments, the metallization pattern 326 has a different size than the metallization pattern 322. For example, the conductive lines and/or vias of the metallization pattern 326 may be wider or thicker than the conductive lines and/or vias of the metallization pattern 322. Further, the metallization pattern 326 may be formed to a greater pitch than the metallization pattern 322.

The metallization pattern 326 includes some portions which are designated to have particular functions. The grating 326rf is a portion of the metallization pattern which is used during transmission and receiving to direct radio frequency waves toward the subsequently formed antenna 332a (see FIG. 41A). Although FIG. 36B shows the grating 326rf coupled together on both ends, in some embodiments, the grating 326rf may be a comb, connected only on one end. The grating 326rf may be coupled to ground. The antenna 326a is a portion of the metallization pattern which is used to transmit and receive signals during operation. The antenna 326a is coupled to the second integrated circuit device 50B. The antenna 326a can be a patch antenna or a microstrip antenna and its placement in proximity to the second integrated circuit device 50B provides reduced impedance and return loss.

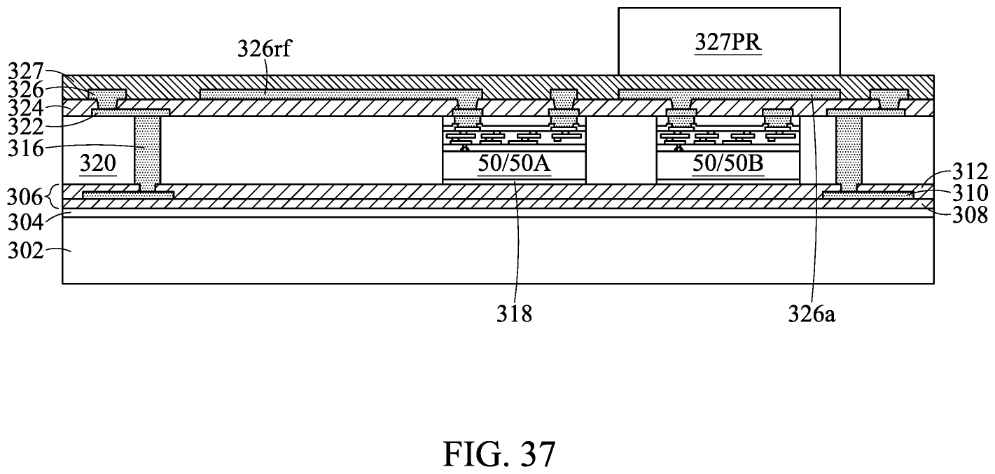

In FIG. 37, a high-k dielectric layer 327 is deposited on the metallization pattern 326 and the dielectric layer 324. The high-k dielectric layer 327 may be deposited using a low temperature process so that thermal expansion mismatch between the dielectric layer 324, the encapsulant 320, and the high-k dielectric layer 327 is kept lower to reduce warpage and/or delamination between the layers. In one embodiment, the dielectric layer 327 may be formed by an e-gun or by laser CVD at a low temperature below 200° C., such as between about 150° C. and 200° C. In such embodiments, the high-k dielectric layer 327 may be made of titanium oxide (e.g, TiO₂) with a k value between about 83-100, SrTiO₃ (STO) with a k value of about 200, BaSrTiO₃ (BST) with a k value between about 250-300, BaTiO₃ (BTO) with a k value of about 500, PbZrTiO₃ (PZT) with a k value between about 1000 and 1500, or combinations thereof.

In another embodiment, the high-k dielectric layer 327 may be deposited using a liquid-phase or spin-on-glass silicon oxide with a k value between about 4.0 and 4.2 using a low temperature curing between about 20° C. and about 200° C. to harden. In another embodiment, the high-k dielectric layer 327 may be deposited using a liquid-phase high-k polymer (e.g., PBO, PI, BCB, etc.) with a low temperature curing between about 20° C. and about 200° C. to harden. In another embodiment, the high-k dielectric layer 327 may be deposited using liquid-phase silicon nitride (SiNₓ) with a k value of about 6.9 or other high-k dielectric in liquid-phase with a low temperature curing between about 200° C. and about 250° C. to remove solvent and harden. In yet another embodiment, the high-k dielectric layer 327 may be deposited using a CVD process such as atmospheric pressure CVD (APCVD), sub-atmospheric CVD (SACVD), plasma enhanced CVD (PECVD), metal organic CVD (MOCVD), or the like to deposit silicon oxide, silicon nitride, and/or silicon oxynitride at a process temperature between about 160° C. and 200° C. In still another embodiment, the high-k dielectric layer 327 may be deposited using a CVD process such as the aforementioned CVD processes to deposit a multi-layer film including ZrO₂, Al₂O₃, and ZrO₂ (ZAZ) with a k value of about 13.6 at a process temperature between about 200° C. and 220° C., or substituting other high-k films, such as ZrO₂, Al₂O₃, HfOₓ, HfSiOₓ, ZrTiOₓ, TaOₓ, TiO₂, the like, or combinations thereof.

The high-k dielectric layer 327 is used to provide the ability for transmitting and/or receiving a high-frequency signal for the antenna 326a. As such, the material of the high-k dielectric layer 327 is selected to have a high k value suitable for the transmission and/or reception of a high frequency signal, such as a 28 GHz, 77 GHz, or 120 GHz nominal frequency signal (e.g., 29-38 GHz, and 77-120 GHz). Utilizing a high-k dielectric layer 327 adjacent the antenna 326a will increase the RF oscillation frequency for the antenna proportional to the k-value. In other words, the higher k-value of the high-k dielectric layer 327, the higher frequency RF signal is able to be transmitted/received by the antenna 326a. The thickness of the high-k dielectric layer 327 may be between about 0.005 μm and about 50 μm or more, such as up to about 100 μm, depending on the material selected. Utilizing low temperature processes can prevent delamination. For example, titanium oxide would otherwise be prone to delamination for thicknesses greater than 3 μm, but may be deposited to a thickness of 35 μm to about 100 μm utilizing low temperature processes.

Following the deposition of the high-k dielectric layer 327, a photoresist is deposited over the high-k dielectric layer 327 and patterned to form a mask 327PR over the high-k dielectric layer 327. The photoresist may be deposited and patterned using acceptable techniques, such as those discussed above with respect to other photoresists.

In FIG. 38, the mask 327PR is used to protect a section of the high-k dielectric layer 327 under the mask 327PR from being etched away during an etching process. A wet or dry etch may be used to remove the exposed sections of the high-k dielectric layer 327, revealing the dielectric layer 324 and the metallization pattern 326. A remaining high-k region of the high-k dielectric layer 327 after etching the high-k dielectric layer 327 is referred to as the high-k zone 327. Enlarged views of the edge of the high-k zone are provided in the callout circles labeled (A), (B), and (C), which demonstrate various options of the interface between the high-k zone 327 and the antenna 326a. In the callout (A), the high-k zone 327 has a sidewall which extends wider than a sidewall of the antenna 326a so that a portion of the dielectric layer 324 is contacted by the high-k zone 327 and the high-k zone 327 laterally encapsulates the antenna 326a (at least on one side). In the callout (B), the high-k zone 327 has a sidewall which is aligned to the sidewall of the antenna 326a (at least on one side). In the callout (C), the high-k zone 327 has a sidewall which is disposed over a section of the antenna 326a (at least on one side), or in other words, the antenna 326a is wider than the high-k zone 327. In some embodiments, two or more of the variations of (A), (B), or (C) may be combined on a single embodiment for example on different edges of the high-k zone 327. Each edge of the high-k zone 327 can be the variation (A), (B), or (C), independently of the others.

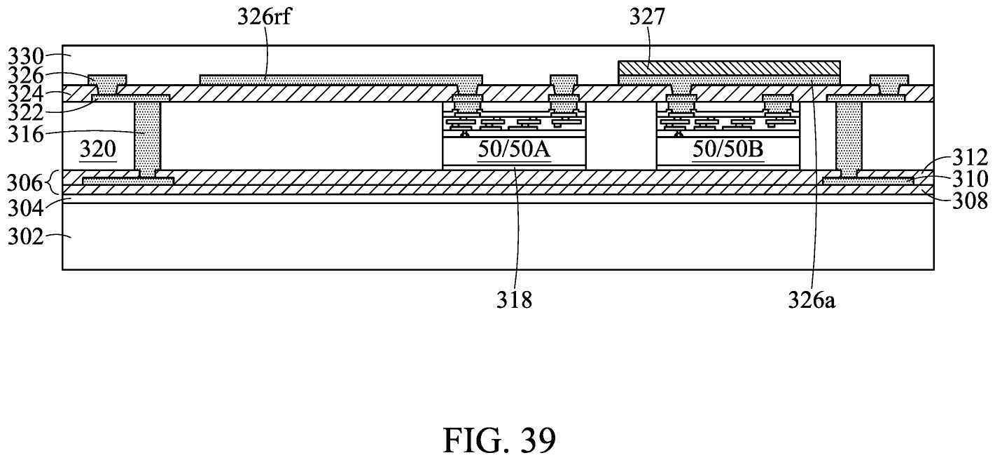

In FIG. 39, the dielectric layer 330 is deposited on the metallization pattern 328, the dielectric layer 324, and the high-k zone 327. The dielectric layer 330 may be formed in a manner similar to the dielectric layer 324, and may be formed of a similar material as the dielectric layer 324. For example, the dielectric layer 230 may be formed of a low-k material, such as a polymer like PBO, PI, or the like, having a k-value between about 2.5 and 3.0.

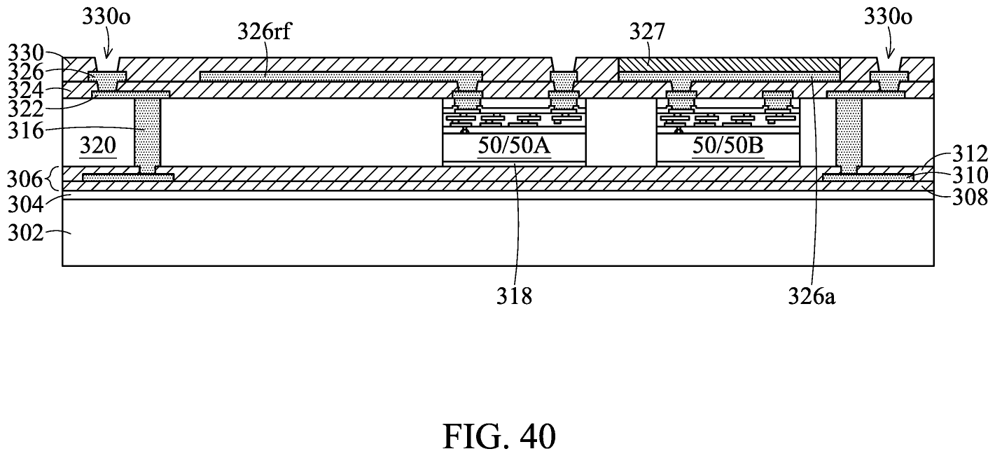

In FIG. 40, the dielectric layer 330 is planarized to remove the dielectric layer 330 over the high-k zone 327, thereby leveling the upper surface of the dielectric layer 330 with an upper surface of the high-k zone 327. The planarization process may be for example, a CMP process, using the high-k zone 327 as a CMP stop. Next, the dielectric layer 324 is patterned to form openings 330o exposing portions of the metallization pattern 328. The patterning may be by an acceptable process, such as by exposing and developing the dielectric layer 330 to light when the dielectric layer 330 is a photo-sensitive material or by etching using, for example, an anisotropic etch.

In FIGS. 41A and 41B, the metallization pattern 332 is formed. FIG. 41A is a cross-sectional view continuing from FIG. 40. FIG. 41B is a top down view of a portion of the structure of FIG. 41A. The metallization pattern 332 includes portions on and extending along the major surface of the dielectric layer 330. The metallization pattern 332 further includes portions extending through the openings 330o of the dielectric layer 330 to physically and electrically couple the metallization pattern 328. The metallization pattern 332 may be formed in a similar manner and of a similar material as the metallization pattern 328. In some embodiments, the metallization pattern 332 has a different size than the metallization pattern 328. For example, the conductive lines and/or vias of the metallization pattern 332 may be wider or thicker than the conductive lines and/or vias of the metallization pattern 328. Further, the metallization pattern 332 may be formed to a greater pitch than the metallization pattern 328.

The metallization pattern 332 includes some portions which are designated to have particular functions. The grating 332rf is a portion of the metallization pattern which is used during transmission and receiving to direct radio frequency waves toward and away from the antenna 326a. Although FIG. 41B shows the grating 332rf coupled together on both ends, in some embodiments, the grating 332rf may be a comb, connected only on one end. The grating 332rf may be coupled to ground. The antenna 332a is a portion of the metallization pattern which is used to transmit and receive signals during operation. The antenna 332a is coupled to the first integrated circuit device 50A. The antenna 332a can be a patch antenna or a microstrip antenna and its placement in proximity to the first integrated circuit device 50A provides reduced impedance and return loss for the antenna 332a.

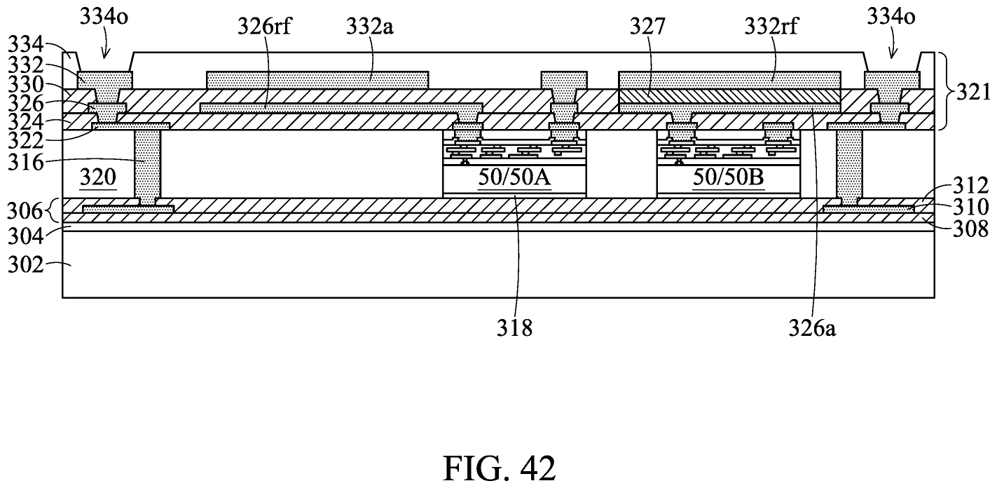

In FIG. 42, the dielectric layer 334 is deposited on the metallization pattern 332 and the dielectric layer 330. The dielectric layer 334 may be formed in a manner similar to the dielectric layer 324, and may be formed of the same material as the dielectric layer 324. Preferably, the dielectric layer 334 is formed using a low-temperature process, such as by a polymer (e.g., PBO, PI, BCB, etc.) spin coating and low temperature curing and hardening between about 180° C. and about 230° C. The dielectric layer 334 is the topmost dielectric layer of the front-side redistribution structure 321. As such, all of the metallization patterns of the front-side redistribution structure 321 (e.g., the metallization patterns 322, 328, and 332) are disposed between the dielectric layer 334 and the integrated circuit dies 50. Further, all of the intermediate dielectric layers of the front-side redistribution structure 321 (e.g., the dielectric layers 324 and 330) are disposed between the dielectric layer 334 and the integrated circuit dies 50. Next, the dielectric layer 334 is patterned to form openings 334o exposing portions of the metallization pattern 332. The patterning may be by an acceptable process, such as by exposing and developing the dielectric layer 334 to light when the dielectric layer 334 is a photo-sensitive material or by etching using, for example, an anisotropic etch.

In FIG. 43, UBMs 338 are formed for external connection to the front-side redistribution structure 321. The UBMs 338 have bump portions on and extending along the major surface of the dielectric layer 334, and have via portions extending through the dielectric layer 334 to physically and electrically couple the metallization pattern 332. As a result, the UBMs 338 are electrically coupled to the through vias 3163 and the integrated circuit dies 50. The UBMs 338 may be formed of the same material as the metallization pattern 332. In some embodiments, the UBMs 338 have a different size than the metallization patterns 322, 328, and 332.

Conductive connectors 350 are formed on the UBMs 338. The conductive connectors 350 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 350 may include a conductive material such as solder, copper, aluminum, gold, nickel, silver, palladium, tin, the like, or a combination thereof. In some embodiments, the conductive connectors 350 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 350 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

A carrier substrate de-bonding is performed to detach (or “de-bond”) the carrier substrate 302 from the back-side redistribution structure 306, e.g., the dielectric layer 308. In accordance with some embodiments, the de-bonding includes projecting a light such as a laser light or an UV light on the release layer 304 so that the release layer 304 decomposes under the heat of the light and the carrier substrate 302 can be removed. The structure is then flipped over and placed on a tape (not shown).

A singulation process is performed by cutting along scribe line regions 339, e.g., between the first package region 300A and adjacent package regions. The cutting singulates the first package region 300A from the adjacent package regions. The cutting can include sawing, etching, laser cutting and the like.

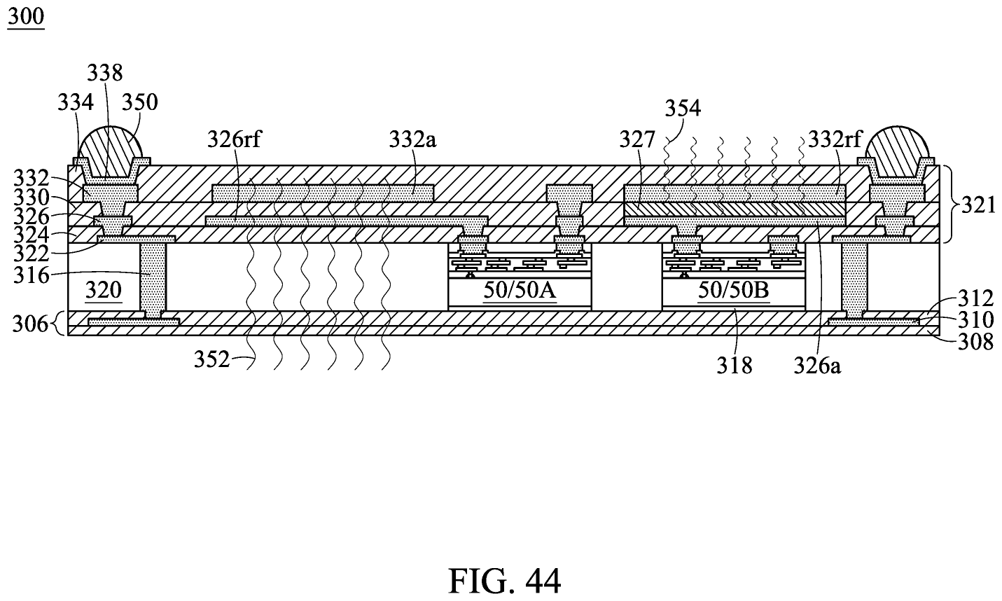

FIG. 44 thus illustrates the completed dual band antenna component 300. As illustrated in FIG. 44, the dual band antenna component 300 may provide transmission and reception of the RF signals 352, which may be transmitted and/or received at frequencies for 3G, 4G, and 5G, and so forth from the antenna 332a (between 2.4 GHz and 12.4 GHz nominal), in a direction away from the conductive connectors 350. The dual band antenna component 300 may also provide transmission and reception of the RF signals 354, which may be transmitted and/or received at frequencies for 6G and automotive radar and the like, from the antenna 326a (between 29 to 38 GHz or 77 to 120 GHz nominal), the second RF signals being, in a direction toward the high-k zone 327 and the conductive connectors 350.

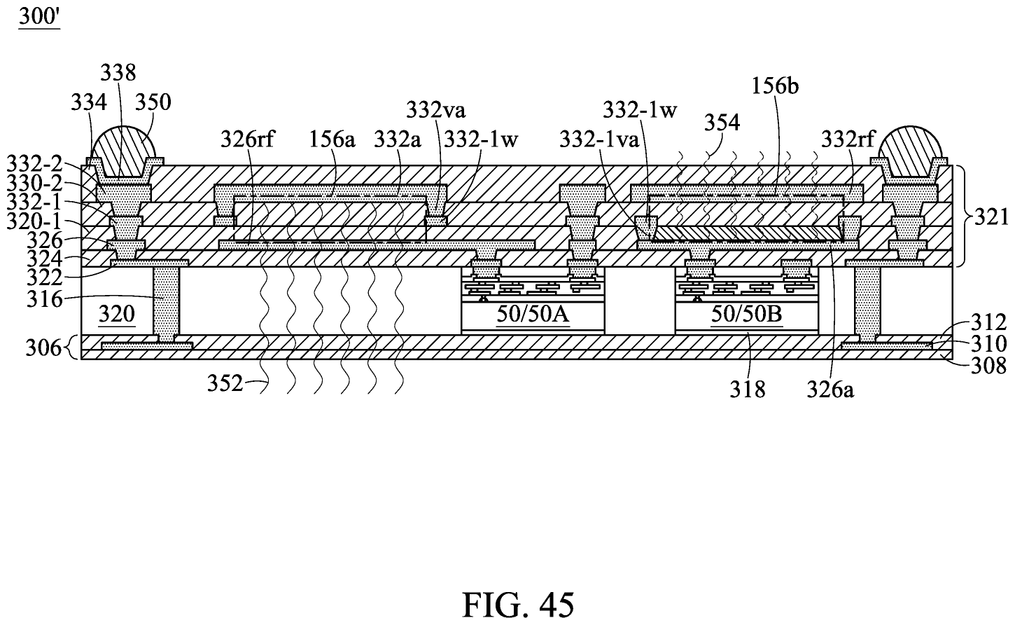

FIG. 45 illustrates a dual band antenna component 300′ which is similar to the dual band antenna component 300 of FIG. 44, except that the dual band antenna component 300′ has been modified to include the oscillation region 156 (FIG. 25) for each of the antennas 326a and 332a as the oscillation region 156b and oscillation region 156a, respectively. Both oscillation regions 156a and 156b are provided for illustration purposes, however, it should be understood that embodiments contemplate the inclusion of one of either oscillation region 156a or oscillation region 156b or both of oscillation region 156a and oscillation region 156b. As illustrated in FIG. 45, the metallization pattern 332-1 forms an oscillation region 156b over the antenna 326a by forming metal wall 332-1w surrounding the oscillation region 156b which is coupled to the antenna 326a by the through via array 332-1va. These are similar in function and design to the through via array 134va and metal wall 126w and can include all the variations which are discussed above. The metallization pattern 332-1 also forms an oscillation region 156a under the antenna 332a by forming metal wall 332-1w surrounding the oscillation region 156a which is coupled to the antenna 332a by the through via array 332va. These are similar in function and design to the through via array 134va and metal wall 126w and can include all the variations which are discussed above.

FIG. 45 can be modified in such a manner by utilizing another dielectric layer (e.g., dielectric layer 330-1 and 330-2 in place of dielectric layer 330) and metallization pattern (e.g., metallization pattern 332-1 and 332-2 in place of metallization pattern 332) in the front-side redistribution structure 321 in order to make room for the oscillation cavities. The same processes and materials can be used to include these additional layers as provided above. It should also be understood that the high-k zone 327 may be extended into both dielectric layer 330-1 and 330-2 utilizing similar materials and processes as described above, for example forming a high-k zone 327 in each of the dielectric layers 330-1 and 330-2. The through via array 332-1va and the metal walls 332-1w are formed at the same process step as the metallization pattern 332-1. The through via array 332va is formed at the same process step as the metallization pattern 332-2.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments of FIGS. 27 through 45 may achieve advantages. Embodiments provide a low-cost dual band package which can transmit and receive in both high frequency ranges and other frequency ranges at the same time. A high-k zone is provided in line with the high frequency antenna so that it can act as an oscillation region suitable for transmitting/receiving high frequency RF for the high frequency antenna. Both antennas further include a metal grate in line with the antennas for directing signals into the antennas or out of the antennas. An integrated fan out process may be used to create the dual band package. Each of the layers have flexible thicknesses. Oscillation cavities as previously described may be used to further enhance and amplify incoming or outgoing signals.

One embodiment is a method including attaching a first device and a second device to a carrier. The method also includes encapsulating the first device and the second device in an encapsulant. The method also includes forming a first redistribution structure over the first device and over the second device. Forming the first redistribution structure may include: forming a first metal grate and first antenna from a first metallization disposed over a first dielectric layer, and forming a second metal grate and a second antenna from a second metallization disposed over a second dielectric layer, the second metal grate aligned vertically to the first antenna, the second antenna aligned vertically to the first metal grate, the second dielectric layer disposed over the first dielectric layer. The method also includes forming front-side connectors coupled to the second metallization.

In an embodiment, the method may include: after forming the first antenna, depositing a high-k dielectric layer over the first antenna and over the first dielectric layer; forming a mask over the first antenna; and etching the high-k dielectric layer free from the mask, a high-k zone remaining over the first antenna. In an embodiment, the method may include: depositing the second dielectric layer over the first dielectric layer and over the high-k zone; and planarizing the second dielectric layer to level an upper surface of the second dielectric layer with an upper surface of the high-k zone. In an embodiment, the high-k zone may include a material having a k value greater than about 6.9 and less than 1500. In an embodiment, the high-k zone may include titanium oxide, STO, BST, BTO, PZT, or combinations thereof. In an embodiment, the high-k dielectric layer is deposited using a process temperature between about 20° C. and about 250° C. In an embodiment, the second antenna is aligned vertically to a region of the encapsulant which is free from devices and metal columns. In an embodiment, forming the first redistribution structure further may include: forming an oscillation region wall from a portion of a third metallization disposed over a third dielectric layer, the third metallization interposed between the first metallization and the second metallization, the oscillation region wall aligned vertically to the first antenna or the second antenna; and forming a via array coupling the oscillation region wall to the first antenna or the second antenna.

Another embodiment is a method including depositing an encapsulant over a carrier to surround a first device, a second device, and a set of conductive pillars extending vertically from the carrier. The method also includes planarizing the encapsulant to level upper surfaces of the encapsulant, conductive pillars, first device, and second device. The method also includes depositing a first dielectric layer over the encapsulant. The method also includes depositing a first metallization over the first dielectric layer, the first metallization including a first metal grate disposed over a free region of the encapsulant and a first antenna coupled to the second device. The method also includes depositing a second dielectric layer over the first metallization. The method also includes depositing a second metallization over the second dielectric layer, the second metallization including a second metal grate disposed over the first antenna and a second antenna disposed over the first metal grate.

In an embodiment, the method may include: prior to depositing the second dielectric layer, depositing a high-k dielectric layer over the first metallization; forming a mask over the high-k dielectric layer, the mask aligned to the first antenna; and etching unmasked portions of the high-k dielectric layer to remove the unmasked portions of the high-k dielectric layer, a remaining portion of the high-k dielectric layer forming a high-k zone disposed on the first antenna. In an embodiment, the high-k zone has a portion which extends down a sidewall of the first antenna and contacts the first dielectric layer. In an embodiment, the method may include: depositing a third dielectric layer over the first metallization, the third dielectric layer interposed between the first dielectric layer and the second dielectric layer; and depositing a third metallization over the third dielectric layer, the third metallization interposed between the first metallization and the second metallization, the third metallization including a metal wall structure surrounding a first oscillation region, the first oscillation region aligned to the first antenna or the second antenna. In an embodiment, the method may include: forming a through-via array coupling the metal wall structure to the first antenna or the second antenna. In an embodiment, the method may include: transmitting and/or receiving first radio frequency (RF) signals on the first antenna through the second metal grate; and transmitting and/or receiving second RF signals on the second antenna through the first metal grate and through the free region of the encapsulant, the first RF signals being 29 to 38 GHz or 77 to 120 GHz nominal, the second RF signals being between 2.4 GHz and 12.4 GHz nominal.

Another embodiment is a device including a first antenna controller and a second antenna controller laterally surrounded by an encapsulant. The device also includes a first redistribution structure disposed over the first antenna controller and the second antenna controller, the first redistribution structure providing an integrated fan out of connectors of the first antenna controller and the second antenna controller, the first redistribution structure may include: a first metallization disposed over a first dielectric layer, the first metallization including a first grate and a first antenna, the first grate coupled to a ground signal, the first antenna coupled to the first antenna controller. The device also includes a second metallization disposed over a second dielectric layer, the second dielectric layer disposed over the first dielectric layer, the second metallization including a second grate and a second antenna, the second grate disposed directly over the first antenna, the second antenna disposed directly over the first grate, the second grate coupled to a ground signal, the second antenna coupled to the second antenna controller.

In an embodiment, the device may include: a high-k zone disposed in the first dielectric layer, the high-k zone interposed between the first antenna and the second grate. In an embodiment, the second antenna is aligned vertically to a free region of the encapsulant. In an embodiment, the first metallization and the second metallization are part of a front-side redistribution structure, and the device may include a set of through-vias embedded in the encapsulant, the set of through-vias coupling the front-side redistribution structure to a back-side redistribution structure. In an embodiment, the device may include a third metallization embedded in a third dielectric layer, the third metallization interposed between the first metallization and the second metallization, the third dielectric layer interposed between the first dielectric layer and the second dielectric layer, the third metallization may include a first metal wall surrounding a first oscillation region, the first oscillation region aligned vertically with the first antenna or the second antenna. In an embodiment, the device may include a via array extending from the first antenna or the second antenna to couple to the first metal wall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
attaching a first device and a second device to a carrier;
encapsulating the first device and the second device in an encapsulant;
forming a first redistribution structure over the first device and over the second device, comprising:
forming a first metal grate and first antenna from a first metallization disposed over a first dielectric layer, and
forming a second metal grate and a second antenna from a second metallization disposed over a second dielectric layer, the second metal grate aligned vertically to the first antenna, the second antenna aligned vertically to the first metal grate, the second dielectric layer disposed over the first dielectric layer; and
forming front-side connectors coupled to the second metallization.

2. The method of claim 1, further comprising:
after forming the first antenna, depositing a high-k dielectric layer over the first antenna and over the first dielectric layer;
forming a mask over the first antenna; and
etching the high-k dielectric layer free from the mask, a high-k zone remaining over the first antenna.

3. The method of claim 2, further comprising:
depositing the second dielectric layer over the first dielectric layer and over the high-k zone; and
planarizing the second dielectric layer to level an upper surface of the second dielectric layer with an upper surface of the high-k zone.

4. The method of claim 2, wherein the high-k zone comprises a material having a k value greater than about 6.9 and less than 1500.

5. The method of claim 2, wherein the high-k zone comprises titanium oxide, STO, BST, BTO, PZT, or combinations thereof.

6. The method of claim 2, wherein the high-k dielectric layer is deposited using a process temperature between about 20° C. and about 250° C.

7. The method of claim 1, wherein the second antenna is aligned vertically to a region of the encapsulant which is free from devices and metal columns.

8. The method of claim 1, wherein forming the first redistribution structure further comprises:
forming an oscillation region wall from a portion of a third metallization disposed over a third dielectric layer, the third metallization interposed between the first metallization and the second metallization, the oscillation region wall aligned vertically to the first antenna or the second antenna; and
forming a via array coupling the oscillation region wall to the first antenna or the second antenna.

9. A method comprising:
depositing an encapsulant over a carrier to surround a first device, a second device, and a set of conductive pillars extending vertically from the carrier;
planarizing the encapsulant to level upper surfaces of the encapsulant, conductive pillars, first device, and second device;
depositing a first dielectric layer over the encapsulant;
depositing a first metallization over the first dielectric layer, the first metallization including a first metal grate disposed over a free region of the encapsulant and a first antenna coupled to the second device;
depositing a second dielectric layer over the first metallization; and
depositing a second metallization over the second dielectric layer, the second metallization including a second metal grate disposed over the first antenna and a second antenna disposed over the first metal grate.

10. The method of claim 9, further comprising:
prior to depositing the second dielectric layer, depositing a high-k dielectric layer over the first metallization;
forming a mask over the high-k dielectric layer, the mask aligned to the first antenna; and
etching unmasked portions of the high-k dielectric layer to remove the unmasked portions of the high-k dielectric layer, a remaining portion of the high-k dielectric layer forming a high-k zone disposed on the first antenna.

11. The method of claim 10, wherein the high-k zone has a portion which extends down a sidewall of the first antenna and contacts the first dielectric layer.

12. The method of claim 9, further comprising:
depositing a third dielectric layer over the first metallization, the third dielectric layer interposed between the first dielectric layer and the second dielectric layer; and
depositing a third metallization over the third dielectric layer, the third metallization interposed between the first metallization and the second metallization, the third metallization including a metal wall structure surrounding a first oscillation region, the first oscillation region aligned to the first antenna or the second antenna.

13. The method of claim 12, further comprising:
forming a through-via array coupling the metal wall structure to the first antenna or the second antenna.

14. The method of claim 9, further comprising:
transmitting and/or receiving first radio frequency (RF) signals on the first antenna through the second metal grate; and
transmitting and/or receiving second RF signals on the second antenna through the first metal grate and through the free region of the encapsulant, the first RF signals being 29 to 38 GHz or 77 to 120 GHz nominal, the second RF signals being between 2.4 GHz and 12.4 GHz nominal.

15. A device comprising:
a first antenna controller and a second antenna controller laterally surrounded by an encapsulant;
a first redistribution structure disposed over the first antenna controller and the second antenna controller, the first redistribution structure providing an integrated fan out of connectors of the first antenna controller and the second antenna controller, the first redistribution structure comprising:
a first metallization disposed over a first dielectric layer, the first metallization including a first grate and a first antenna, the first grate coupled to a ground signal, the first antenna coupled to the first antenna controller; and
a second metallization disposed over a second dielectric layer, the second dielectric layer disposed over the first dielectric layer, the second metallization including a second grate and a second antenna, the second grate disposed directly over the first antenna, the second antenna disposed directly over the first grate, the second grate coupled to a ground signal, the second antenna coupled to the second antenna controller.

16. The device of claim 15, further comprising:
a high-k zone disposed in the first dielectric layer, the high-k zone interposed between the first antenna and the second grate.

17. The device of claim 15, wherein the second antenna is aligned vertically to a free region of the encapsulant.

18. The device of claim 15, wherein the first metallization and the second metallization are part of a front-side redistribution structure, further comprising a set of through-vias embedded in the encapsulant, the set of through-vias coupling the front-side redistribution structure to a back-side redistribution structure.

19. The device of claim 15, further comprising a third metallization embedded in a third dielectric layer, the third metallization interposed between the first metallization and the second metallization, the third dielectric layer interposed between the first dielectric layer and the second dielectric layer, the third metallization comprising a first metal wall surrounding a first oscillation region, the first oscillation region aligned vertically with the first antenna or the second antenna.

20. The device of claim 19, further comprising a via array extending from the first antenna or the second antenna to couple to the first metal wall.
